(19) United States
(12) Patent Application Publication
(10) Pub. No.: US 2026/0304663 A1
(43) Pub. Date: Oct. 1, 2026

(54) SEALING ARRANGEMENT WITH A SEAL HAVING VARYING ELECTRICAL PROPERTIES

(71) Applicant: Greene, Tweed Technologies, Inc., Wilmington, DE (US)

(72) Inventors: Nicholas P. Piacente, Rockville, MD (US); Carmen J. Quartapella, Collegeville, PA (US)

(73) Assignee: Greene, Tweed Technologies, Inc., Wilmington, DE (US)

(21) Appl. No.: 19/090,984

(22) Filed: Mar. 26, 2025

(51) Int. Cl. H05K 5/06; G01N 27/20; G01N 27/24; G01R 1/067

(52) U.S. Cl. CPC H05K 5/069; G01N 27/20; G01N 27/24; G01R 1/06722; H05K 5/061

(57) ABSTRACT

A sealing arrangement may include a housing assembly, a seal, at least one probe assembly, and an insulator. The housing assembly may include a first housing portion and a second housing portion. The housing assembly may define a groove defined by internal surfaces of one or more of the first housing portion or the second housing portion. The seal may have variable electrical properties. The seal may be configured to be received within the groove and abut the first housing portion and the second housing portion. The least one probe assembly may be configured to extend into the groove defined by the housing assembly. The at least one probe assembly may be configured to enable real-time measurements of one or more properties of the seal. The insulator may be configured to electrically insulate at least a portion of the at least one probe assembly from the housing assembly.

### BACKGROUND

Various parts and components used in manufacturing equipment, including seals and gaskets are well known. With respect to seals and gaskets, surfaces within semiconductor manufacturing equipment include sealed areas operating at a variety of pressure regimes, including sub-atmospheric among others, allowing plasma, and/or chemistry to be generated and maintained in portions of the system. A seal or gasket may be attacked by the chemistry, varying thermal conditions, or pressures used in the system. Seal erosion or compression set can lead to a loss of sealing footprint and compromise the pressure integrity of the system. Thus, measuring the reliability of seals and minimizing particulation are highly desired properties in most semiconductor manufacturing applications.

Measuring reliability and degradation rates of seals and gaskets also is a desirable end goal in a wide variety of end applications to maximize effective production life of a seal or gasket, while minimizing the leaks or end effects of compromised seal properties due to degradation or other factors. Other seals can be variably impacted by different reactants and different reactant conditions. Dynamic seals on a moving system are subjected to additional mechanical load which can lead to quicker failure compared to a seal or gasket in a static location. Harsh precursors, plasmas, high-temperature and other conditions can cause different types of seals to wear at variable rates. A majority of such reaction chambers operate under vacuum conditions and use seals throughout the system to maintain the vacuum environment.

Such seals are generally formed of highly chemically-resistant elastomeric materials, that are costly to purchase, so it is understandable that one may not want to replace a seal before replacement is indicated. However, due to the variability in the impact of reactants and conditions on various elastomeric materials used to make the seals, it is not always easy to predict when a seal is compromised and/or when it will be subject to imminent failure. Elastomeric sealing properties as well as other physical properties of the materials can be tested to estimate failures in different environments and that information is used to provide expected seal life information. However, with varying environments, conditions and use expectations, to be safe, one would expect to change out the seal before harm, inconsistency in product outcome or failure to a particular product occurs.

As the products made in such environments are themselves very costly to manufacture, unnecessary maintenance down time and/or failure are even more costly to a manufacturer than replacement of the seals. Thus, effective seal life is a key factor that impacts up-time, use of the system, maintenance scheduling and product failures due to seal material degradation. The chemical, temperature and other process conditions impact the material of the seal and can lead to seal degradation and failure. Such issues also arise in other industries where maintenance costs, seal cost or downtime are costly and/or where the sealing function is key to operation safety, such that seal life monitoring and timely replacement that is cost effective is important.

### SUMMARY

A sealing arrangement may include a housing assembly, a seal, at least one probe assembly, and an insulator. The housing assembly may include a first housing portion and a second housing portion. The housing assembly may define a groove between the first housing portion and the second housing portion. The groove may be defined by internal surfaces of one or more of the first housing portion or the second housing portion. The seal may have variable electrical properties. The seal may be configured to be received within the groove and abut the first housing portion and the second housing portion. The least one probe assembly may be configured to extend into the groove defined by the housing assembly. The at least one probe assembly may be configured to enable real-time measurements of one or more properties of the seal. The insulator may be configured to electrically insulate at least a portion of the at least one probe assembly from the housing assembly.

When extending into the groove, a probe tip of the at least one probe assembly may be proximate to an outer surface of the seal. When extending into the groove, a probe tip of the at least one probe assembly may be spaced away from an outer surface of the seal. When extending into the groove, a probe tip of the at least one probe assembly may abut an outer surface of the seal. The seal may be an electrically conductive o-ring. The electrically conductive o-ring may be homogenously conductive. The electrically conductive o-ring may include a homogenous material that is electrically conductive. The at least one probe assembly may include an electrical contact configured to abut the electrically conductive o-ring. The electrical contact may be a spring-loaded contact configured to compensate for mechanical interference between the electrically conductive o-ring and the at least one probe assembly. The electrical contact may be a first electrical contact. The at least one probe assembly may include a second electrical contact configured to abut the housing assembly. The first electrical contact may be electrically connected to an input lead. The second electrical contact may be electrically connected to an output lead. The input lead may be configured to apply an electric current to the electrically conductive o-ring that travels through the electrically conductive o-ring and out of the output lead to measure the one or more properties of the electrically conductive o-ring while the electrically conductive o-ring remains within the groove.

The housing assembly may include a clamp assembly configured to clamp the first housing portion to the second housing portion. The at least one probe assembly may extend through the clamp assembly. The first housing portion may be a first pipe section having a first flange and the second housing portion may be a second pipe section having a second flange. The real-time measurements of the one or more properties may enable determination of a performance metric of the seal based on the real-time measurements. The performance metric may enable determination of a remaining life of the seal and/or an estimated maintenance interval for the seal. The at least one probe assembly may include a sensor configured to provide the real-time measurements of the one or more properties of the seal. The sensor may include one or more of a pressure sensor, a temperature sensor, a humidity sensor, a proximity sensor, an optical sensor, a vibration sensor, or a capacitive sensor. The electrical properties of the seal may include one or more of resistance, capacitance, or inductance. The electrical properties of the seal may vary when the seal is compressed by a force, when a current is applied to the seal, when the seal is exposed to application conditions, when the seal is chemically attacked, when the seal is physically attacked, and/or when the seal is exposed to a varying temperature. The at least one probe assembly may be configured to send and receive wireless messages.

A sealing arrangement may include a first pipe section defining a first flange, a second pipe section defining a second flange, a clamp assembly, a seal, and a probe assembly. The clamp assembly may be configured to abut the first flange and the second flange, for example, to clamp the first pipe section to the second pipe section. The seal may have one or more variable electrical properties. The seal may be configured to be received within a groove defined by the first flange, the second flange, and the clamp assembly. The seal may be configured to abut the first flange and the second flange when the first pipe section is clamped to the second pipe section, The probe assembly may be configured to extend through the clamp assembly and into the groove. The probe assembly may be configured to enable real-time measurements of the one or more variable electrical properties of the seal.

A sealing arrangement may include a housing, an electrically conductive seal, a probe assembly, and an insulator. The housing may include a first housing portion and a second housing portion. The housing may define a groove between the first housing portion and the second housing portion. The groove may be defined by internal surfaces of one or more of the first housing portion or the second housing portion. The electrically conductive seal may be configured to be received within the groove and abut the first housing portion and the second housing portion. The probe assembly may be configured to extend into the groove defined by the housing assembly. The probe assembly may be configured to enable real-time measurements of one or more electrical properties of the electrically conductive seal. The probe assembly may include a first electrical contact and a second electrical contact. The first electrical contact may be configured to abut the electrically conductive seal. The second electrical contact may be configured to abut the first housing portion or the second housing portion. The insulator may be configured to electrically insulate at least a portion of the probe assembly from the housing.

A sealing arrangement may include a body, an electrically conductive seal, a probe assembly, and an insulator. The body may define a groove between a first internal surface of the body and a second internal surface of the body. The electrically conductive seal may be configured to be received within the groove and abut the first housing portion and the second housing portion. The probe assembly may be configured to extend into the groove defined by the body. The probe assembly may be configured to enable real-time measurements of one or more electrical properties of the electrically conductive seal. The probe assembly may include a first electrical contact configured to abut the electrically conductive seal and a second electrical contact configured to abut the first housing portion or the second housing portion. The insulator may be configured to electrically insulate at least a portion of the probe assembly from the body.

A method of measuring an installed conductive seal is provided herein. An input voltage may be applied to a seal measuring circuit. The seal measuring circuit may include a power source, the conductive seal, and a reference resistor. A first resistance of the reference resistor may be measured. An output voltage of the measuring circuit may be measured. A second resistance of the conductive seal may be calculated, for example, by comparing the input voltage, the output voltage, and the first resistance of the reference resistor.

A method of processing one or more measured electrical properties of an installed conductive seal is provided herein. One or more electrical measurements of the conductive seal may be received. A performance metric of the conductive seal may be determined based on the one or more electrical measurements. A remaining life of the conductive seal or an estimated maintenance interval for the conductive seal may be determined, based on the determined performance metric.

### BRIEF DESCRIPTION OF THE DRAWINGS

FIG. 1A is a diagram of an example sealing arrangement.

FIG. 1B is a diagram of an example seal measuring circuit.

FIG. 2A is a perspective view of another example sealing arrangement.

FIG. 2B is a cross-section view of the example sealing arrangement shown in FIG. 2A.

FIG. 3A is a cross-section view of another example sealing arrangement.

FIG. 3B is a detailed partial cross-section view of the example sealing arrangement shown in FIG. 3A.

FIG. 4A is a perspective view of another example sealing arrangement.

FIG. 4B is a cross-section view of the example sealing arrangement shown in FIG. 4A.

FIG. 4C is a detailed partial cross-section view of the example sealing arrangement shown in FIG. 4A.

FIG. 5A is a perspective view of another example sealing arrangement.

FIG. 5B is a cross-section view of the example sealing arrangement shown in FIG. 5A.

FIG. 5C is a perspective view of an example probe assembly for use in the example sealing arrangement shown in FIG. 5A.

FIG. 5D is a detailed partial cross-section view of the example sealing arrangement shown in FIG. 5A.

FIG. 6 is a detailed partial cross-section view of another example probe assembly.

FIG. 7 is a detailed partial cross-section view of another example probe assembly.

FIG. 8A is a top view of another example sealing arrangement.

FIG. 8B is a cross-section view of the example sealing arrangement shown in FIG. 8A.

FIG. 9A is a perspective view of another example sealing arrangement.

FIG. 9B is a cross-section view of the example sealing arrangement shown in FIG. 9A.

FIG. 10A is a flowchart of an example method of measuring electrical properties of an installed seal.

FIG. 10B is a flowchart of an example method of measuring and performing calculations associated with an installed seal.

FIG. 11 is a flowchart of an example method of processing measured electrical properties of an installed seal.

FIG. 12 is a block diagram of an example computing device for use with a sealing arrangement.

FIG. 13 is a block diagram of an example computing network system for use with a sealing arrangement.

FIG. 14 is a block diagram of an example probe assembly for use with a sealing arrangement.

### DETAILED DESCRIPTION

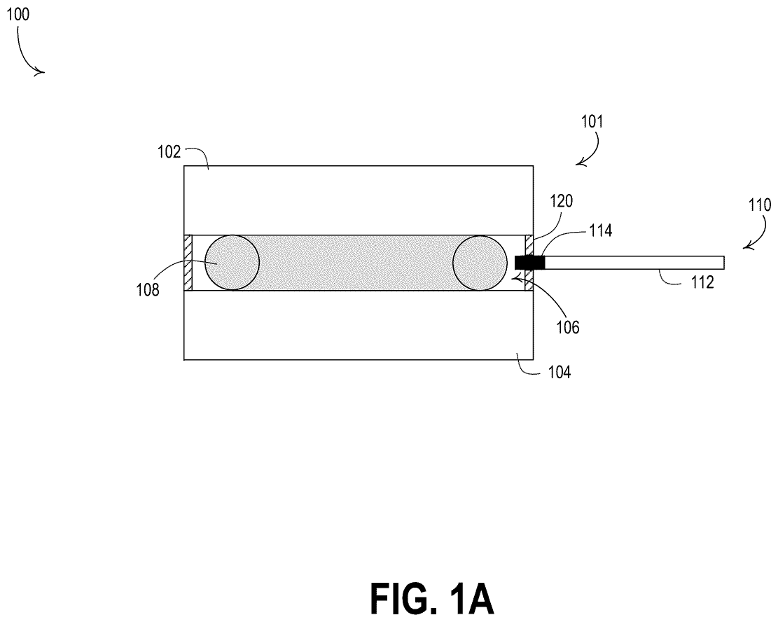

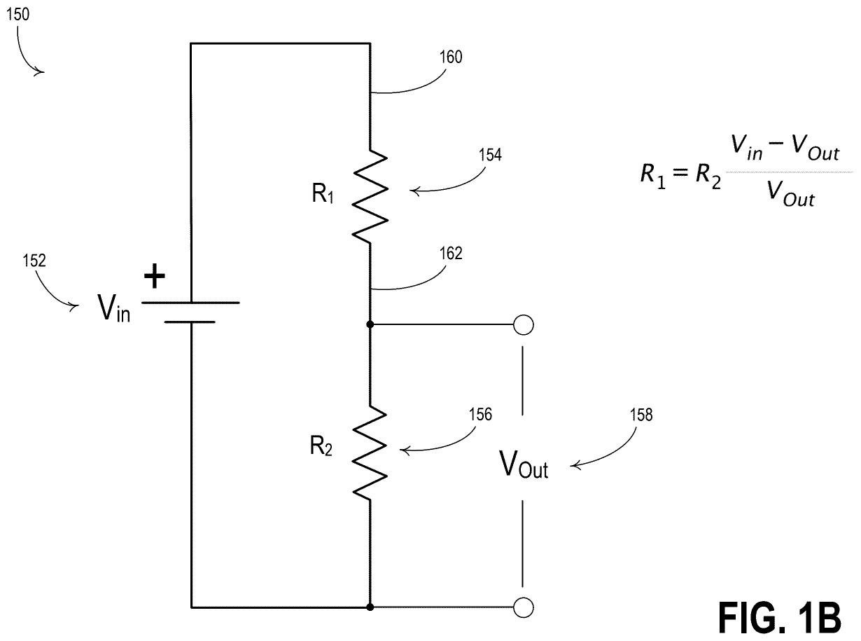

FIG. 1A is a cross-section view of an example sealing arrangement 100. The sealing arrangement 100 may include a housing assembly 101, a seal 108, a probe assembly 110, and an insulator 120. The housing assembly 101 may include a first housing portion 102 and a second housing portion 104. The housing assembly 101 may define a groove 106 between the first housing portion 102 and the second housing portion 104. For example, the groove 106 may be defined by internal surfaces of one or more of the first housing portion 102 or the second housing portion 104. The insulator 120 may be a spacer ring that is configured to surround the seal 108. The probe assembly 110 may be configured to extend through the insulator 120. For example, the insulator 120 may define an opening that is configured to receive the probe assembly 110 therethrough.

The seal 108 may be an o-ring, a t-seal, a u-cup, an x-ring, a d-ring, a square ring, a wiper seal, etc. The seal 108 may be configured to provide a seal between the first housing portion 102 and the second housing portion 104. The seal 108 may be configured to be received within the groove 106. For example, the seal 108 may abut the first housing portion 102 and the second housing portion 104. The seal 108 may have variable electrical properties. The variable electrical properties of the seal 108 may include resistance, capacitance, and/or inductance. For example, one or more of the variable electrical properties of the seal 108 may change when the seal 108 is compressed by a force (e.g., greater than a threshold force), when a current is applied to the seal 108, when the seal 108 is exposed to application conditions, when the seal 108 is chemically attacked, when the seal 108 is physically attacked, and/or when the seal 108 is exposed to a varying temperature condition. The variable electrical properties of the seal 108 may include resistance, capacitance, and/or inductance. Additionally or alternatively, the seal 108 may be an electrically conductive seal. For example, the seal 108 may be homogenously conductive and/or may be made from a homogenous material that is electrically conductive.

The probe assembly 110 may be configured to extend into the groove 106 defined by the housing assembly 101. The probe assembly 110 may include a probe body 112 and a probe tip 114. The probe tip 114 may be configured to be proximate to an outer surface of the seal 108, for example, when the probe assembly 110 extends into the groove 106. The probe tip 114 may be spaced away (e.g., by a predetermined distance) from the outer surface of the seal 108, for example, when the probe assembly 110 extends into the groove 106. The probe tip 114 may abut the outer surface of the seal 108, for example, when the probe assembly 110 extends into the groove 106.

The probe assembly 110 may include one or more electrical contacts as described herein. A first electrical contact of the one or more electrical contacts may be configured to abut the seal 108. The first electrical contact may be a spring-loaded contact that is configured to compensate for mechanical interference between the seal 108 and the probe assembly 110. A second electrical contact of the one or more electrical contacts may be configured to abut the housing assembly 101. The first electrical contact may be electrically connected to an input lead and the second electrical contact may be electrically connected to an output lead. The input lead may be configured to apply an electric current to the seal 108 that travels through the seal and out of the output lead, for example, to measure the one or more properties of the seal 108 while the seal 108 remains within the groove 106.

The probe assembly 110 may include one or more sensors as described herein. The one or more sensors may be configured to provide the real-time measurements of the one or more properties of the seal 108. The one or more sensors may include a pressure sensor, a temperature sensor, a humidity sensor, a proximity sensor, an optical sensor, a vibration sensor, and/or a capacitive sensor. The probe assembly 110 may be configured to send and receive wireless messages (e.g., via Bluetooth, zigbee, wifi, etc.).

The probe assembly 110 may be configured to enable real-time measurements of one or more properties of the seal 108. The real-time measurements of the one or more properties may enable determination of a performance metric of the seal 108 based on the real-time measurements. The performance metric may enable determination of a remaining life of the seal 108 and/or an estimated maintenance interval for the seal 108. The insulator 120 may be configured to electrically insulate at least a portion of the probe assembly 110 from the housing assembly 101. For example, the insulator 120 may be configured to abut the first housing portion 102 and the second housing portion 104.

In examples, the housing assembly 101 may further include a clamp assembly, as described herein. The clamp assembly may be configured to clamp the first housing portion 102 to the second housing portion 104. The probe assembly 110 may extend through the clamp assembly. The first housing portion 102 may be a first pipe section having a first flange and the second housing portion 104 may be a second pipe section having a second flange.

FIG. 1B depicts an example seal measuring circuit 150. The seal measuring circuit 150 may include a power source 152 that provides an input voltage, a seal 154, a reference resistor 156, and an output voltage 158. The seal 154 may be an o-ring, a t-seal, a u-cup, an x-ring, a d-ring, a square ring, a wiper seal, etc. The seal 154 may have variable electrical properties. The variable electrical properties of the seal 154 may include resistance, capacitance, and/or inductance. For example, the electrical properties of the seal 154 may change when the seal 154 is compressed by a force (e.g., greater than a threshold force), when a current is applied to the seal 154, when the seal 154 is exposed to application conditions, when the seal 154 is chemically attacked, when the seal 154 is physically attacked, and/or when the seal 154 is exposed to a varying temperature condition.

In examples, the seal 154 may be composed of conductive materials such that the seal 154 has a variable resistance that is a function of the state (e.g., such as sealing performance) of the seal 154. For example, the resistance of the electrically conductive seal 154 may change as the state of the seal 154 changes. The seal measuring circuit 150 may further include an input lead 160 and an output lead 162. The input lead 160 and the output lead 162 may be used to measure one or more electrical properties (e.g., such as resistance, capacitance, inductance, and/or other electrical properties) of the seal 154, for example, while the seal 154 remains installed in its installed location. The measured one or more electrical properties may be correlated to the state of the seal 154 and/or seal life (e.g., remaining seal life).

The seal measuring circuit 150 may be a voltage divider circuit, as shown in FIG. 1B, where the resistance of the seal 154 may be determined by comparing the input voltage of the power source 152, the output voltage 158, and the resistance of the reference resistor 156. For example, the resistance of the seal 154 may be determined using Equation 1.

$${R}_{1} = {R}_{2} \frac{{V}_{i n} - {V}_{o u t}}{{V}_{i n}} \qquad ( 1 )$$

Although FIG. 1B depicts the seal measuring circuit 150 as a voltage divider circuit, it should be appreciated that the seal measuring circuit 150 can be any number of resistance measuring circuits that capture the resistance of the electrically conductive seal 154.

The seal measuring circuit 150 may enable sensing of the seal 154. Sensing may be enabled by applying and measuring the current traveling through the seal 154. Routing such a current through the seal 154 while the seal 154 is installed is a difficult integration challenge. Existing electrical conditions around industrial equipment (e.g., such as grounded equipment) may make it difficult to apply and measure a current traveling through the seal 154. Certain modifications to sealing hardware may impact seal reliability and implementation as a retrofit solution.

A method of electrically connecting smart materials (e.g., such as an electrically conductive seal and/or the seal measuring circuit 150) to broader systems, in applications where sensing of an electrically conductive seal's electrical properties (e.g., resistance, capacitance, inductance, etc.) is desired while the seal 154 (e.g., an electrically conductive seal) is installed and sealing in a gland. Electrically connecting the seal 154 to broader systems may enable electrical connection to a broader electronic circuit, for example, to extract electrical information from the material (e.g., such as the electrically conductive seal) to be processed by a microcontroller, and turned into useful information. Raw and/or processed data can then be relayed to external systems (e.g., such as cloud computing systems), which can use the information to determine the seals performance, remaining useful life (RUL), maintenance schedules, and/or other important information. Obtaining and processing electrical information from smart materials can optimize lifetime of seals, ultimately reducing consumable waste, increasing equipment uptime, improving overall equipment effectiveness (OEE) and other manufacturing process metrics, improving safety, and/or reducing unplanned downtime.

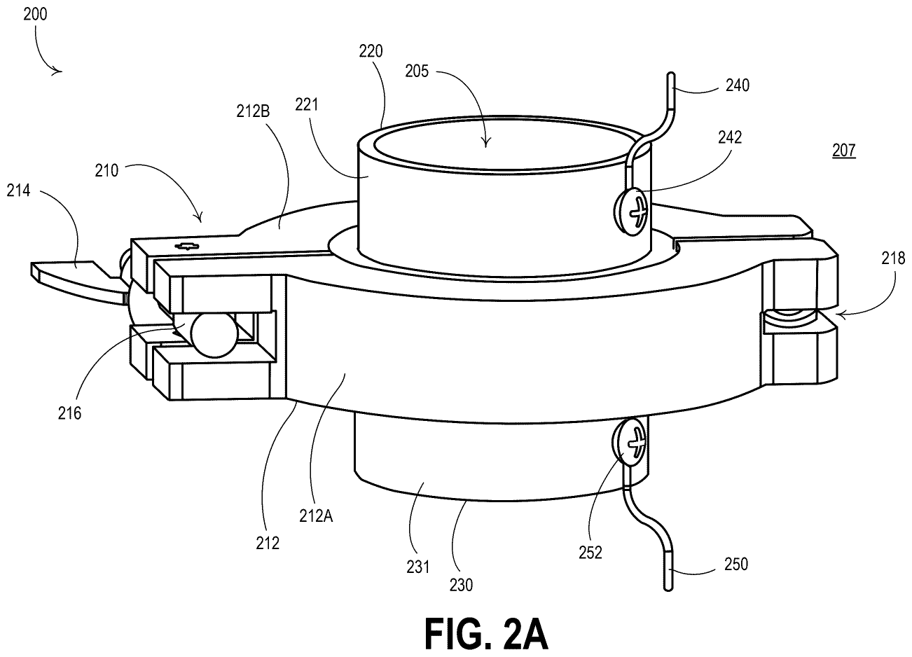

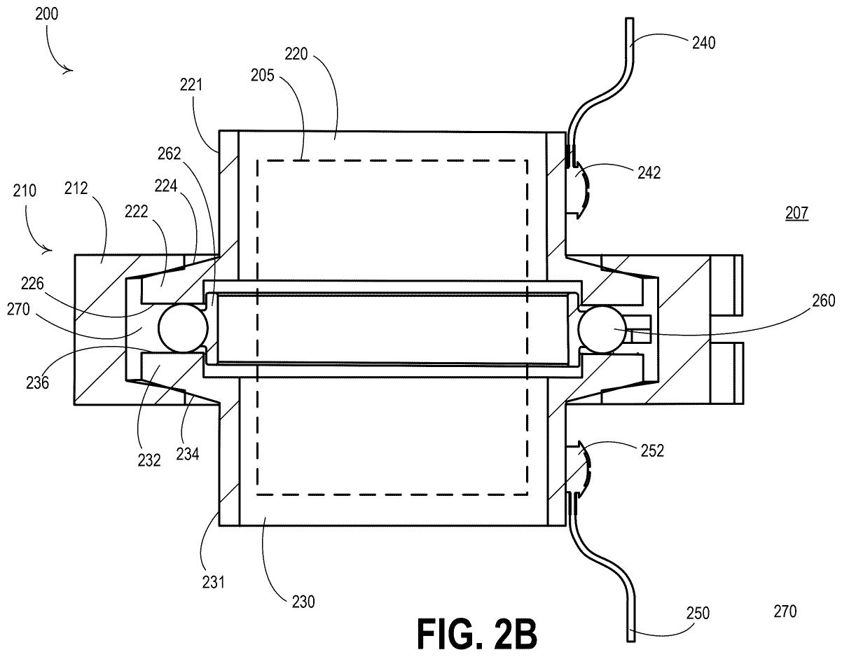

FIGS. 2A-2B depict an example sealing arrangement 200. The sealing arrangement 200 may include a seal 260 (e.g., such as the seal 108 shown in FIG. 1A and/or the seal 154 shown in FIG. 1B) and a centering ring 262. The centering ring 262 may be an inner gasket of the sealing arrangement 200. The seal 260 may be an electrically conductive seal, as described herein. The seal 260 may be configured to be installed between two pipe portions 220, 230. For example, the seal 260 may be configured to provide a seal in a body or housing (e.g., between an upper pipe portion 220 and a lower pipe portion 230). The seal 260 may be an o-ring, a t-seal, a u-cup, an x-ring, a d-ring, a square ring, a wiper seal, etc. The seal 260 may have varying electrical properties. The variable electrical properties of the seal 260 may include resistance, capacitance, and/or inductance. For example, one or more electrical properties of the seal 260 may vary when the seal 260 is compressed by a force, when a current is applied to the seal 260, when the seal 260 is exposed to application conditions, when the seal 260 is chemically attacked, when the seal 260 is physically attacked, and/or when the seal 260 is exposed to a varying temperature.

The seal 260 may be a conductive seal. For example, the seal 260 may include one or more conductive materials having quantum tunneling composite effects. A material having quantum tunneling composite effects may exhibit a conductivity that is higher when subjected to compressive stress than a conductivity of the article when the compressive stress is released. Examples of conductive materials having quantum tunneling composite effects used in seals are described in greater detail in commonly-owned U.S. Patent Publication No. 20220306853A1, filed on Dec. 8, 2021, entitled POLYMER AND ELASTOMER COMPOSITIONS HAVING CARBON NANOSTRUCTURE ADDITIVES AND ARTICLES FORMED THEREFROM FOR USE IN EMI AND RFI SHIELDING AND IN PRESSURE SENSING SEALS HAVING QUANTUM TUNNELING COMPOSITE EFFECTS, the entire disclosure of which is hereby incorporated by reference. The sealing arrangement 200 may be configured to enable measurement of the seal 260, when the seal 260 remains installed between the pipe portions 220, 230.

Additionally or alternatively, the seal 260 may incorporate electrodes. The electrodes may be incorporated into the seal 260, for example, to connect to an elastomer of the seal 260. For example, the electrodes may be stuck into an vulcanized elastomer or molded into the elastomer of the seal 260. In examples, the electrodes may be fixed to the surface of the elastomer of the seal 260.

The upper pipe portion 220 may define a first flange 222, for example, at a distal end of the upper pipe portion 220. The first flange 222 may define an outer surface 224 and an inner surface 226. The inner surface 226 may be a sealing surface of the upper pipe portion 220. The lower pipe portion 230 may define a first flange 232, for example, at a distal end of the upper pipe portion 230. The first flange 232 may define an outer surface 234 and an inner surface 236. The inner surface 236 may be a sealing surface of the upper pipe portion 230.

The sealing arrangement 200 may include a clamp assembly 210. The clamp assembly 210 may be attached to the body or housing (e.g., the two pipe portions 220, 230). The clamp assembly 210 may abut the upper pipe portion 220 and the lower pipe portion 230 to clamp together the pipe portions 220, 230. For example, the clamp assembly 210 may be configured to abut the first flange 222 (e.g., the outer surface 224 of the first flange 222) and the second flange 232 (e.g., the outer surface 234 of the second flange 232). The clamp assembly 210 may be a Klein Flancsche (KF) vacuum fitting clamp. The clamp assembly 210 may include a clamp body 212, a wing nut 214, a threaded post 216, and a pivot joint 218. The clamp body 212 may define a first body portion 212A and a second body portion 212B. The first body portion 212A and the second body portion 212B may be configured to pivot about the pivot joint 218, for example, to secure the upper pipe portion 220 to the lower pipe portion 230. For example, the first body portion 212A and the second body portion 212B may be moved apart to be located over the first flange 222 and the second flange 232, for example, when the seal 260 is located within the groove 270. The first body portion 212A and the second body portion 212B may be moved toward each other to enable the wing nut 214 to be installed on the threaded post 216. When the wing nut 214 is installed on the threaded post 216, the wing nut 214 may be tightened on the threaded post 216 to move the first body portion 212A and the second body portion 212B closer to each other around the first flange 222 and the second flange 232. As the wing nut 214 is tightened, the first body portion 212A may abut the outer surface 224 of the first flange 222 and the second body portion 212B may abut the outer surface 234 of the second flange 232, for example, to clamp the two pipe portions 220, 230 together with the seal 260 between the two pipe portions 220, 230.

When the two pipe portions 220, 230 are clamped together, an inner pipe area 205 may be defined by the two pipe portions 220, 230. The inner pipe area 205 may be sealed from the external environment 207 by the sealing arrangement 200. The clamp assembly 210 and the two pipe portions 220, 230 may define a groove 270. The groove 270 may be defined between the clamp body 212, the first flange 222 (e.g., the inner surface 226 of the first flange 222), and the second flange 232 (e.g., the inner surface 236 of the second flange 232). The groove 270 may represent the open volume area configured to enable separation of the inner pipe area 205 from the external environment 207. The seal 260 may be located within the groove 270, for example, between the inner surface 226 and the inner surface 236.

The sealing arrangement 200 may include an input lead 240 (e.g., such as the input lead 160 shown in FIG. 1B) and an output lead 250 (e.g., such as the output lead 162 shown in FIG. 1B). The input lead 240 may be attached to the upper pipe portion 220 and the output lead 250 may be attached to the lower pipe portion 230. For example, the input lead 240 may be attached to the upper pipe portion 220 via a first fastener 242 and the output lead 250 may be attached to the lower pipe portion 230 via a second fastener 252. It should be appreciated that the input lead 240 and/or the output lead 250 may be attached to the pipe portions 220, 230 using alternative methods such as welding.

The input lead 240 and the output lead 250 may be used to measure one or more electrical properties of the seal 260 within the groove 270. In the example shown in FIGS. 2A and 2B, current may flow from the input lead 240, through the upper pipe portion 220, through the conductive seal 260, through the lower pipe portion 230, and out of the output lead 250. The upper pipe portion 220 and the lower pipe portion 230 may include a conductive material (e.g., such as aluminum (e.g., an aluminum alloy), copper (e.g., a copper alloy), and/or Stainless Steel. For example, the upper pipe portion 220 and the lower pipe portion 230 may be made of the conductive material. The centering ring 262 and the clamp assembly 210 may include non-conductive materials. For example, the centering ring 262 may be made of plastic such as polytetrafluoroethylene (PTFE) and/or polyetheretherketone (PEEK) and the clamp assembly 210 may be made of PTFE and/or PEEK. The centering ring 262 and the clamp assembly 210 may be electrically isolated from the seal 260.

The 260 may be bonded. For example, an insulating adhesive or a conductive adhesive may be added to the sealing arrangement 200.

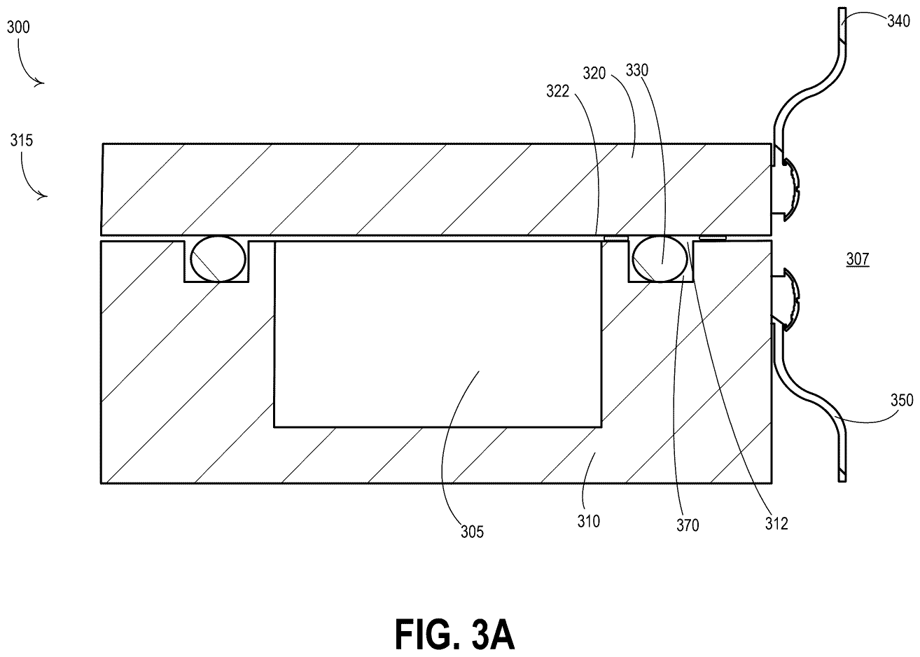

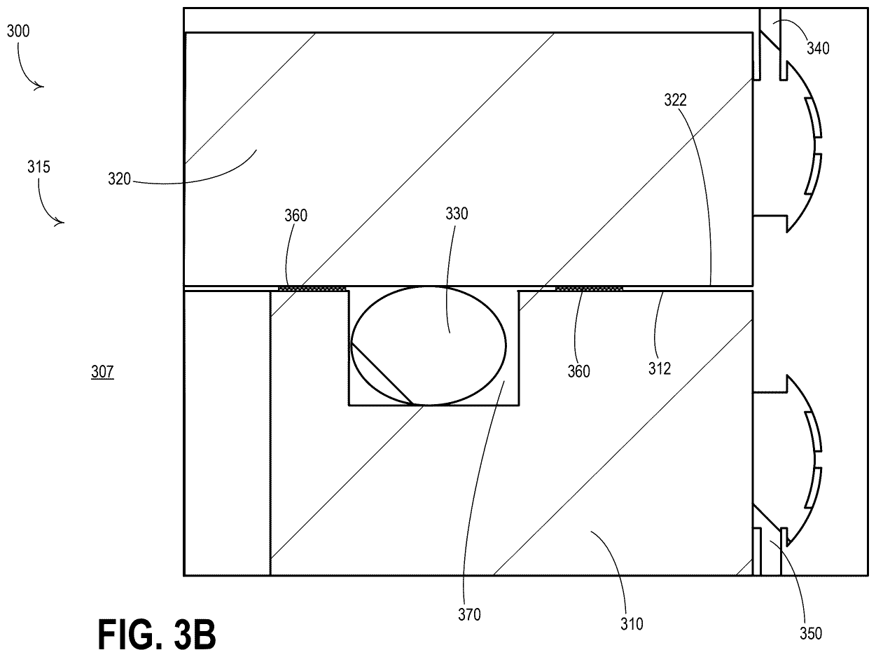

FIGS. 3A-3B depict another example sealing arrangement 300. The sealing arrangement 300 may include a seal 330 (e.g., such as the seal 108 shown in FIG. 1A, the seal 154 shown in FIG. 1B, and/or the seal 260 shown in FIG. 2B). The sealing arrangement 300 may be referred to as an electrically conductive seal assembly. The seal 330 may be configured to be installed between two body portions 310, 320 of a hardware assembly 315. The hardware assembly 315 may be a body, a housing, etc. For example, the sealing arrangement 300 may be configured to provide a seal between an upper portion 320 and a lower portion 310. The seal 330 may be an o-ring, a t-seal, a u-cup, an x-ring, a d-ring, a square ring, a wiper seal, etc. The seal 330 may have one or more varying electrical properties. The one or more varying electrical properties of the seal 330 may include resistance, capacitance, and/or inductance. For example, one or more electrical properties of the seal 330 may vary when the seal 330 is compressed by a force, when a current is applied to the seal 330, when the seal 330 is exposed to application conditions, when the seal 330 is chemically attacked, when the seal 330 is physically attacked, and/or when the seal 330 is exposed to a varying temperature.

The seal 330 may be a conductive seal. For example, the seal 330 may include one or more conductive materials having quantum tunneling composite effects. The sealing arrangement 300 may be configured to enable measurement of the seal 330, when the seal 330 remains installed between the portions 320, 310.

Additionally or alternatively, the 330 may incorporate electrodes. The electrodes may be incorporated into the seal 330, for example, to connect to an elastomer of the seal 330. For example, the electrodes may be stuck into an vulcanized elastomer or molded into the elastomer of the seal 330. In examples, the electrodes may be fixed to the surface of the elastomer of the seal 330.

The upper portion 320 may define a lower surface 322. The lower surface 322 may be a bottom surface of the upper portion 320. The lower portion 310 may define an upper surface 312. The upper surface 312 may be a top surface of the lower portion 310.

The sealing arrangement 300 may include one or more non-conductive spacers 360. The non-conductive spacers 360 may be attached to the two portions 320, 310. The nonconductive spacers 360 may abut the upper portion 320 and the lower portion 310, for example, to electrically isolate the two portions 310, 320. For example, the non-conductive spacers 360 may be configured to abut the lower surface 322 of the upper portion 320, and the upper surface 312 of the lower portion 310.

An inner area 305 may be defined between the two portions 320 and 310. The inner area 305 may be sealed from the external environment 307 by the sealing arrangement 300. The lower portion 310 and/or the upper portion 320 may define a groove 370. The groove 370 may be configured to receive the seal 330. The conductive seal 330 may be located between the upper surface 312 and the lower surface 322, for example, within the groove 370.

The sealing arrangement 300 may include an input lead 340 (e.g., such as the input lead 160 shown in FIG. 1B and/or the input lead 240 in FIG. 2A) and an output lead 350 (e.g., such as the output lead 162 shown in FIG. 1B and/or the output lead 250 in FIG. 2A). The input lead 340 may be attached to the upper portion 320 and the output lead 350 may be attached to the lower portion 310. For example, the input lead 340 may be attached to the upper portion 320 via a first fastener 342 and the output lead 350 may be attached to the lower portion 330 via a second fastener 352. It should be appreciated that the input lead 340 and/or the output lead 350 may be attached to the portions 320, 310 by welding.

The input lead 340 and the output lead 350 may be used to measure one or more electrical properties of the seal 330 within the groove 370. The example shown in FIGS. 3A and 3B may be a more generalized approach than the sealing application shown in FIGS. 2A and 2B. In the example shown in FIGS. 3A and 3B, the groove 370 may be a machined rectangular element in the upper surface 312 of the lower portion 310. In examples, current may flow from the input lead 340, through the upper portion 320, through the seal 330, through the lower portion 310, and out of the output lead 350. The upper portion 320 and the lower portion 310 may include a conductive material. For example, the upper portion 320 and the lower portion 310 may be made of stainless steel and/or aluminum. The non-conductive spacers 360 may be made of non-conductive materials. For example, the non-conductive spacers 360 may be made of PTFE and/or PEEK. The non-conductive spacers 360 may be a non-conductive coating, or another method that may electrically isolate the upper portion 320 from the lower portion 310.

The seal 330 may be bonded. For example, an insulating adhesive or a conductive adhesive may be added to the sealing arrangement 300.

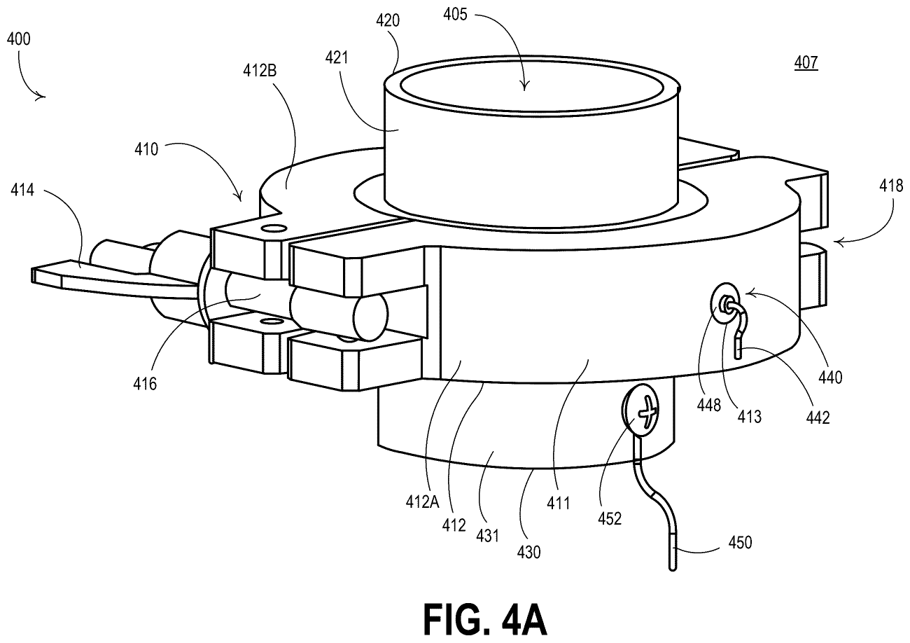

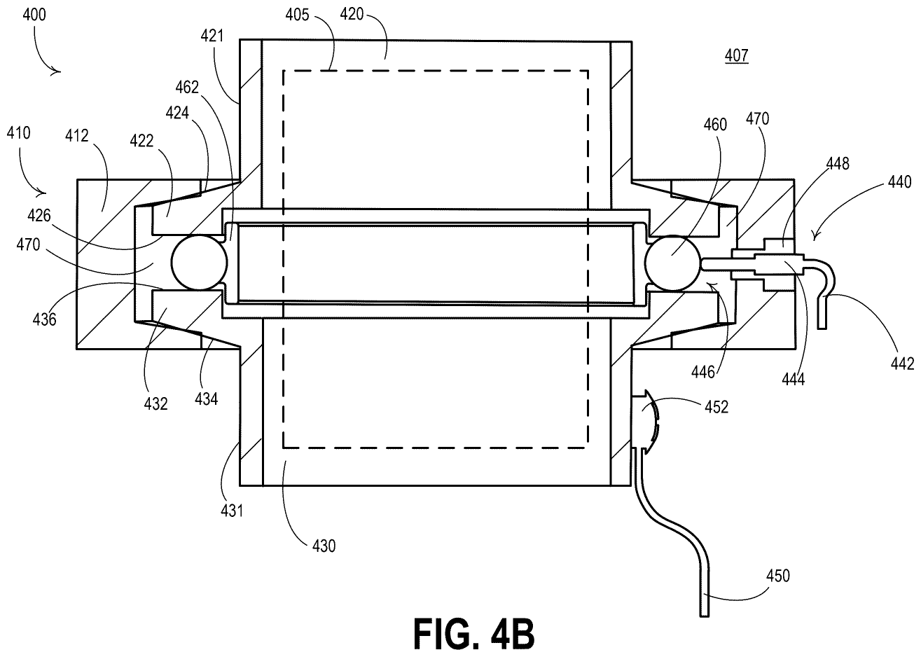

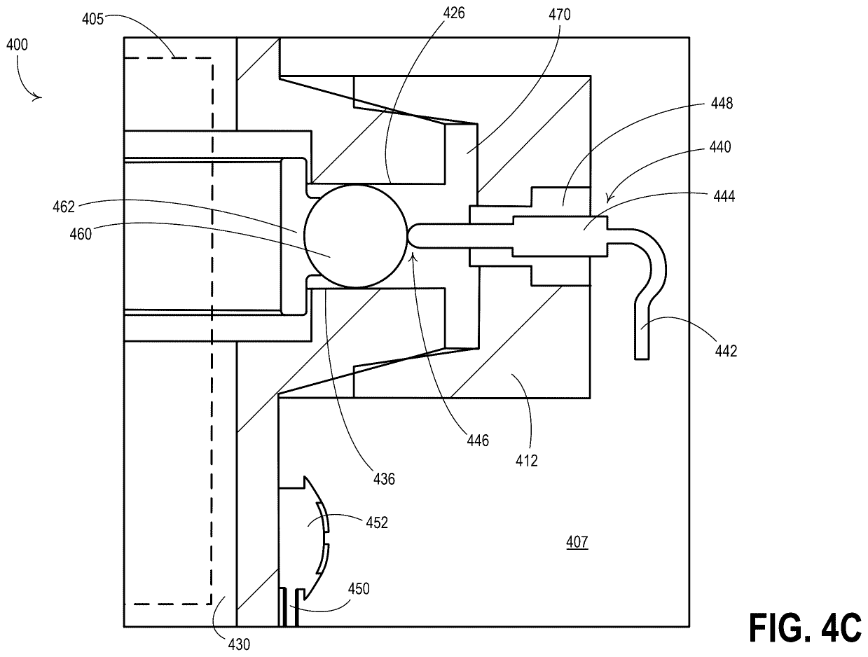

FIGS. 4A-4C depict another example sealing arrangement 400. The sealing arrangement 400 may include a seal 460 (e.g., such as the seal 108 shown in FIG. 1A, the seal 154 shown in FIG. 1B, the seal 260 shown in FIGS. 2A-2B, and/or the seal 330 shown in FIGS. 3A-3B) and a centering ring 462. The sealing arrangement 400 may include a body and/or a housing that defines two pipe portions 420, 430. The centering ring 462 may be an inner gasket (e.g., between the seal 460 and an inner area 405 of the body and/or housing) of the sealing arrangement 300. The seal 460 may be configured to be installed between the two pipe portions 420, 430. For example, the seal 460 may be configured to provide a seal between an upper pipe portion 420 and a lower pipe portion 430. The seal 460 may be an o-ring, a t-seal, a u-cup, an x-ring, a d-ring, a square ring, a wiper seal, etc. The seal 460 may have one or more varying electrical properties. The one or more varying electrical properties of the seal 460 may include resistance, capacitance, and/or inductance. For example, one or more electrical properties of the seal 460 may vary when the seal 460 is compressed by a force, when a current is applied to the seal 460, when the seal 460 is exposed to application conditions, when the seal 460 is chemically attacked, when the seal 460 is physically attacked, and/or when the seal 460 is exposed to a varying temperature.

The seal 460 may be a conductive seal. For example, the seal 460 may include one or more conductive materials having quantum tunneling composite effects. The sealing arrangement 400 may be configured to enable measurement of the seal 460, when the seal 460 remains installed between the pipe portions 420, 430.

Additionally or alternatively, the seal 460 may incorporate electrodes. The electrodes may be incorporated into the seal 460, for example, to connect to an elastomer of the seal 460. For example, the electrodes may be stuck into a vulcanized elastomer or molded into the elastomer of the seal 460. In examples, the electrodes may be fixed to the surface of the elastomer of the seal 460.

The upper pipe portion 420 may define a first flange 422, for example, at a distal end of the upper pipe portion 420. The first flange 422 may define an outer surface 424 and a sealing inner surface 426. The inner sealing surface 426 may be a seal contact surface of the upper pipe portion 420. The lower pipe portion 430 may define a first flange 432, for example, at a distal end of the lower pipe portion 430. The first flange 432 may define an outer surface 434 and an inner sealing surface 436. The inner sealing surface 436 may be a seal contact surface of the lower pipe portion 430.

The sealing arrangement 400 may include a clamp assembly 410. The clamp assembly 410 may be attached to the two pipe portions 420, 430. The clamp assembly 410 may abut the upper pipe portion 420 and the lower pipe portion 430 to clamp together the pipe portions 420, 430. For example, the clamp assembly 410 may be configured to abut the first flange 422 (e.g., the outer surface 424 of the first flange 422) and the second flange 432 (e.g., the outer surface 434 of the second flange 432). The clamp assembly 410 may be a Klein Flancsche (KF) vacuum fitting clamp. The clamp assembly 410 may include a clamp body 412, a wing nut 414, a threaded post 416, and a pivot joint 418. The clamp body 412 may define an opening 413. The clamp body 412 may define a first body portion 412A and a second body portion 412B. The first body portion 412A and the second body portion 412B may be configured to pivot about the pivot joint 418, for example, to secure the upper pipe portion 420 to the lower pipe portion 430. For example, the first body portion 412A and the second body portion 412B may be moved apart to be located over the first flange 422 and the second flange 432. The first body portion 412A and the second body portion 412B may be moved toward each other to enable the wing nut 414 to be installed on the threaded post 416. When the wing nut 214 is installed on the threaded post 416, the wing nut 414 may be tightened on the threaded post 416 to move the first body portion 412A and the second body portion 412B closer to each other around the first flange 422 and the second flange 432. As the wing nut 414 is tightened, the first body portion 412A may abut the outer surface 424 of the first flange 422 and the second body portion 412B may abut the outer surface 434 of the second flange 432, for example, to clamp the two pipe portions 420, 430 together with the conductive seal 460 between the two pipe portions 420, 430.

When the two pipe portions 420, 430 are clamped together, an inner pipe area 405 may be defined by the two pipe portions 420, 430. The inner pipe area 405 may be sealed from the external environment 407 by the seal 460. The clamp assembly 410 and the two pipe portions 420, 430 may define a groove 470. The groove 470 may be defined between the clamp body 412, the first flange 422 (e.g., the inner sealing surface 426 of the first flange 422), and the second flange 432 (e.g., the inner sealing surface 436 of the second flange 432). The groove 470 may represent the open volume area configured to enable separation of the inner pipe area 405 from the external environment 407. The seal 460 may be located within the groove 470, for example, between the inner sealing surface 426 and the inner sealing surface 436.

The sealing arrangement 400 may include a probe assembly 440 and an output lead 450 (e.g., such as the output lead 162 shown in FIG. 1B). The probe assembly 440 may include an input lead 442 (e.g., such as the input lead 160 shown in FIG. 1B), an insulator 448 and an input probe 444. The input probe 444 may be an electrical probe, an acoustic probe, a piezoelectric probe, and/or a pressure differential probe. It should be appreciated that the input probe 444 is not limited to these examples and instead may be another type of probe. The input probe 444 may define a probe tip 446 at a distal end of the input probe 444. The insulator 448 may be an insulating sleeve that surrounds at least a portion of the input probe 444. For example, the input probe 444 may be received within the insulator 448. The probe tip 446 may extend beyond the insulator 448. The probe assembly 440 may be configured to extend through the clamp body 412 and into the groove 470, for example, between the inner sealing surface 426 and the inner sealing surface 436. For example, the probe assembly 440 may extend through the opening 413. The opening 413 may be located on the atmospheric (e.g., external environment 407) side of the clamp assembly 410, which does not interfere with the inner surface 426 or the inner sealing surface 436. The input lead 442 may be attached to the probe 444. In examples, the probe tip 446 may be electrically connected to the seal 460. For example, the probe tip 446 may abut the seal 460 (e.g., an outer surface of the seal 460). The probe 444 (e.g., the probe tip 446) may be compliant as to not puncture or damage the seal 460 when making the electrical connection. For example, the input probe 444 (e.g., the probe tip 446) may include a spring loaded contact. The input probe 444 (e.g., the spring loaded contact) may be configured to compensate for mechanical interference between the seal 460 and the probe assembly 440, for example, which may be caused by compression of the fitting, an increase in seal CX geometry due to thermal expansion, tolerance stack up, and/or other reasons. In examples, the probe assembly 440 may be configured to remain spaced away from the seal 460 within the groove 470. For example, a sensor on the probe assembly 440 may perform measurements and/or readings (e.g., real-time measurements and/or readings) on the seal 460 within the groove 470. The first probe assembly 440 may perform one or more calculations based on the measurements and/or readings.

The upper pipe portion 420 and the output lead 450 may be attached to the lower pipe portion 430. For example, the output lead 450 may be attached to the lower pipe portion 430 via a fastener 452. It should be appreciated that the input lead 442 and/or the output lead 450 may be attached to the pipe portions 420, 430 using alternative methods.

In the example shown in FIGS. 4A-4C, current may flow from the input lead 442, through the probe 444, through the electrically conductive seal 460, through the lower pipe portion 430, and out of the output lead 450 using the probe tip 446. The probe 444 and the lower pipe portion 430 may include a conductive material. For example, the probe 444 and the lower pipe portion 430 may include a stainless steel and/or aluminum. The centering ring 462 and the clamp assembly 410 may include non-conductive materials. For example, the centering ring 462 may be made of PTFE and/or PEEK and the clamp assembly 410 may be made of PTFE and/or PEEK. The centering ring 462 and the clamp assembly 410 may be electrically isolated from the seal 460.

The input lead 442 and the output lead 450 may be used to measure one or more electrical properties of the seal 460 within the groove 470. Current may flow from the input lead 442, through the input probe 444, through the seal 460, through the lower portion 410, and out of the output lead 450. The lower portion 410 may include a conductive material. For example, the lower portion 410 may be made of a stainless steel and/or aluminum.

The probe assembly 440 may be configured to perform wireless communications. For example, the probe assembly 440 may be Bluetooth-enabled. The probe assembly 440 may be configured to send one or more measurements and/or calculations associated with the seal 460 to another computing device. The seal 460 may be bonded. For example, an insulating adhesive or a conductive adhesive may be added to the sealing arrangement 400.

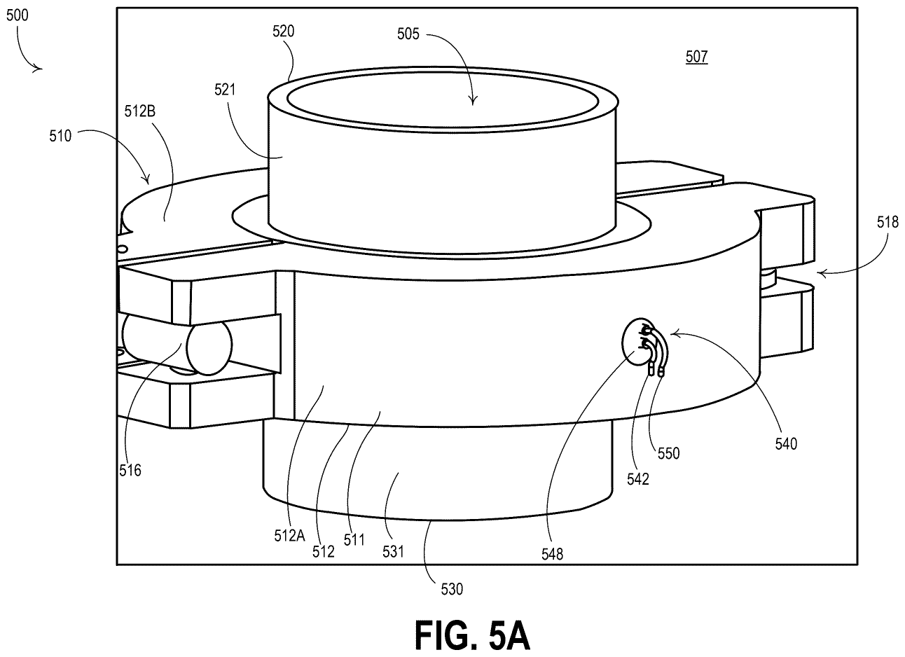

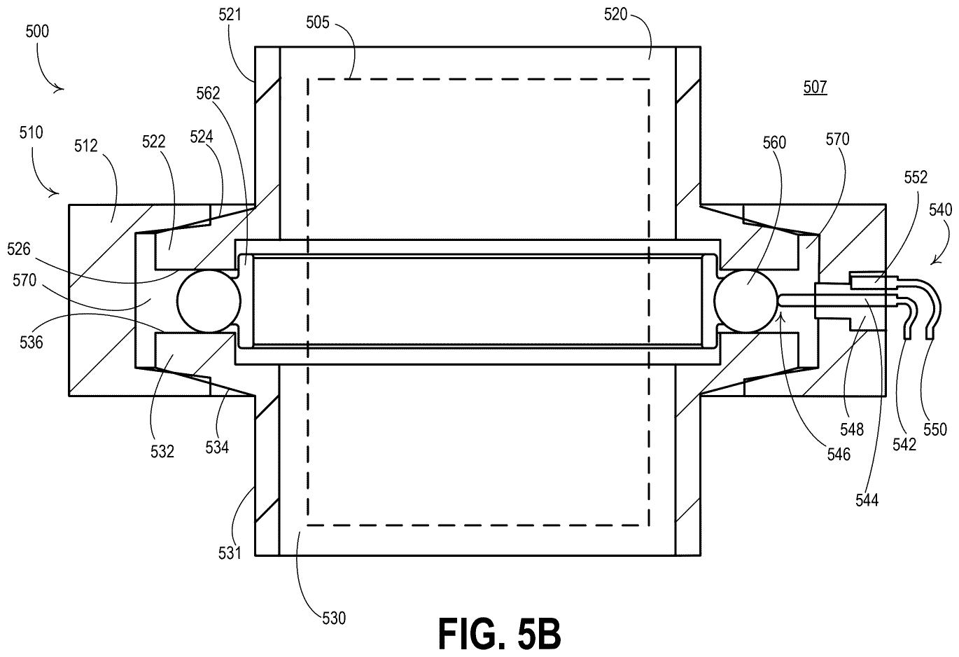

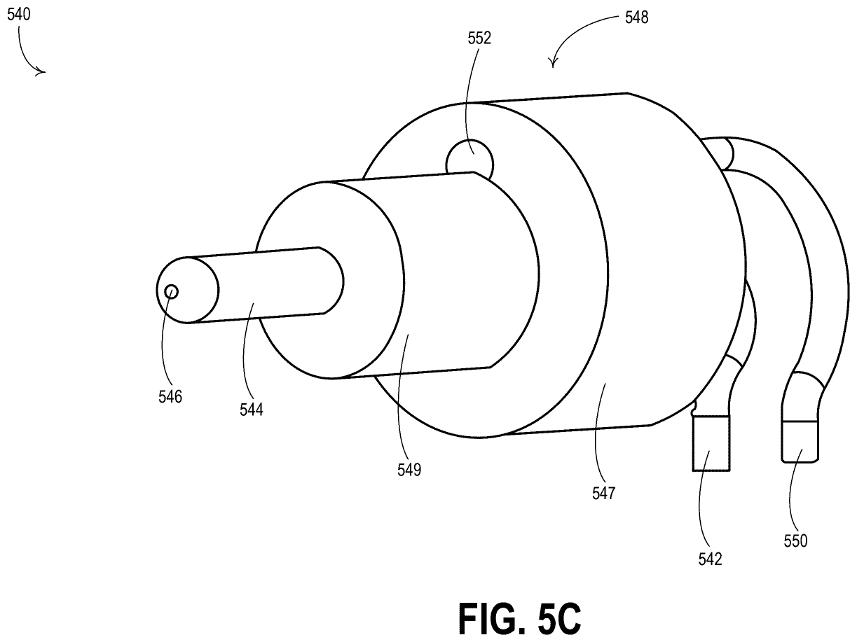

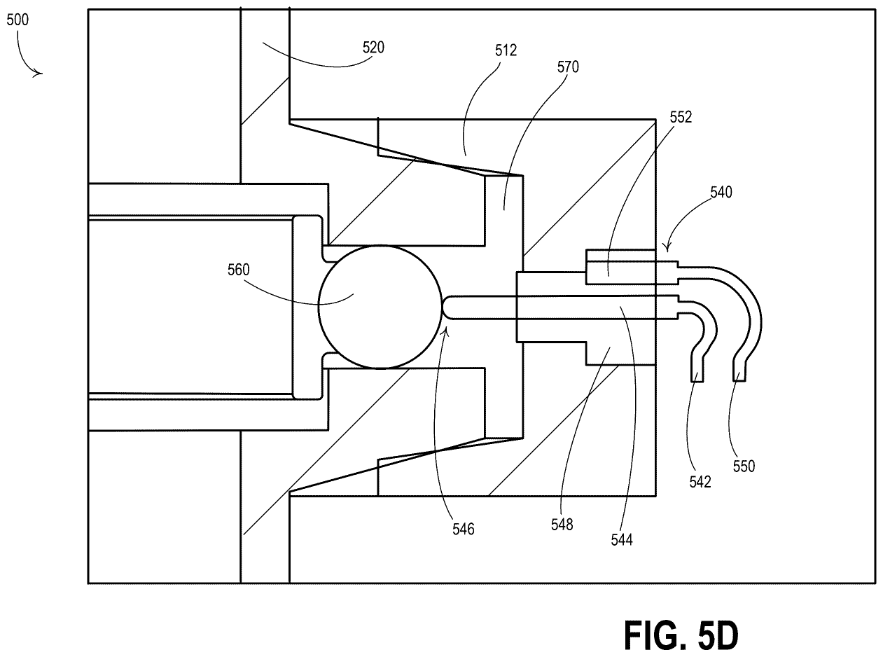

FIGS. 5A-5D depict another example sealing arrangement 500. The sealing arrangement 500 may include a seal 560 (e.g., such as the seal 108 shown in FIG. 1A, the seal 154 shown in FIG. 1B, the seal 260 shown in FIG. 2B, the seal 360 shown in FIGS. 3A-3B, and/or the seal 460 shown in FIGS. 4A-4C) and centering ring 562. The centering ring 562 may be an inner gasket (e.g., between the seal 560 and an inner area 505 of the body and/or housing of the sealing arrangement 500) of the sealing arrangement 500. The seal 560 may be configured to be installed between two pipe portions 520, 530. For example, the seal 560 may be configured to provide a seal between an upper pipe portion 520 and a lower pipe portion 530. The seal 560 may be an o-ring, a t-seal, a u-cup, an x-ring, a d-ring, a square ring, a wiper seal, etc. The seal 560 may have one or more varying electrical properties. The one or more varying electrical properties of the seal 560 may include resistance, capacitance, and/or inductance. For example, one or more electrical properties of the seal 560 may vary when the seal 560 is compressed by a force, when a current is applied to the seal 560, when the seal 560 is exposed to application conditions, when the seal 560 is chemically attacked, when the seal 560 is physically attacked, and/or when the seal 560 is exposed to a varying temperature.

The seal 560 may be a conductive seal. For example, the seal 560 may include one or more conductive materials having quantum tunneling composite effects. The sealing arrangement 500 may be configured to enable measurement of the seal 560, when the seal 560 remains installed between the pipe portions 520, 530.

Additionally or alternatively, the seal 560 may incorporate electrodes. The electrodes may be incorporated into the seal 560, for example, to connect to an elastomer of the seal 560. For example, the electrodes may be stuck into a vulcanized elastomer or molded into the elastomer of the seal 560. In examples, the electrodes may be fixed to the surface of the elastomer of the seal 560.

The upper pipe portion 520 may define a first flange 522, for example, at a distal end of the upper pipe portion 520. The first flange 522 may define an outer surface 524 and an inner surface 526. The inner surface 526 may be a sealing surface of the upper pipe portion 520. The lower pipe portion 530 may define a first flange 532, for example, at a distal end of the lower pipe portion 530. The first flange 532 may define an outer surface 534 and an inner surface 536. The inner surface 536 may be a sealing surface of the lower pipe portion 530.

The sealing arrangement 500 may include a clamp assembly 510. The clamp assembly 510 may be attached to the two pipe portions 520, 530. The clamp assembly 510 may abut the upper pipe portion 520 and the lower pipe portion 530 to clamp together the pipe portions 520, 530. For example, the clamp assembly 510 may be configured to abut the first flange 522 (e.g., the outer surface 524 of the first flange 522) and the second flange 532 (e.g., the outer surface 534 of the second flange 532). The clamp assembly 510 may be a Klein Flancsche (KF) vacuum fitting clamp. The clamp assembly 510 may include a clamp body 512, a wing nut (e.g., such as the wing nut 216 shown in FIG. 2A and/or the wing nut 416 shown in FIG. 4A), a threaded post 516, and a pivot joint 518. The clamp body 512 may define a first body portion 512A and a second body portion 512B. The first body portion 512A and the second body portion 512B may be configured to pivot about the pivot joint 518, for example, to secure the upper pipe portion 520 to the lower pipe portion 530. For example, the first body portion 512A and the second body portion 512B may be moved apart to be located over the first flange 522 and the second flange 532. The first body portion 512A and the second body portion 512B may be moved toward each other to enable the wing nut to be installed on the threaded post 516. When the wing nut is installed on the threaded post 516, the wing nut may be tightened on the threaded post 516 to move the first body portion 512A and the second body portion 512B closer to each other around the first flange 522 and the second flange 532. As the wing nut is tightened, the first body portion 512A may abut the outer surface 524 of the first flange 522 and the second body portion 512B may abut the outer surface 534 of the second flange 532, for example, to clamp the two pipe portions 520, 530 together with the seal 560 between the two pipe portions 520, 530.

When the two pipe portions 520, 530 are clamped together, an inner pipe area 505 may be defined by the two pipe portions 520, 530. The inner pipe area 505 may be sealed from the external environment 507 by the seal 560. The clamp assembly 510 and the two pipe portions 520, 530 may define a groove 570. The groove 570 may be defined between the clamp body 512, the first flange 522 (e.g., the inner sealing surface 526 of the first flange 522), and the second flange 532 (e.g., the inner sealing surface 536 of the second flange 532). The groove 570 may represent the open volume area configured to enable separation of the inner pipe area 505 from the external environment 507. The seal 560 may be located within the groove 570, for example, between the inner sealing surface 526 and the inner sealing surface 536.

The sealing arrangement 500 may include a probe assembly 540. The probe assembly 540 may include an input lead 542 (e.g., such as the input lead 160 shown in FIG. 1B) and an output lead 550 (e.g., such as the output lead 162 shown in FIG. 1B). The probe assembly 540 may further include an insulator 548, an input probe 544, a probe tip 546, an output probe 552, and an output lead 550. The input probe 544 may be an electrical probe, an acoustic probe, a piezoelectric probe, and/or a pressure differential probe. It should be appreciated that the input probe 544 is not limited to these examples and instead may be another type of probe. The insulator 548 may define a first insulator portion 547 and a second insulator portion 549. The insulator 548 may be an insulating sleeve that surrounds at least a portion of the input probe 544 and the output probe 552. For example, the input probe 544 and the output probe 552 may be received within the insulator 548 such that the input probe 544 and the output probe 552 are electrically insulated from the clamp body 512. The insulator 548 may be configured to electrically isolate the input probe 544 from the output probe 552. The probe tip 546 may extend beyond the insulator 548.

The probe assembly 540 may be configured to extend through the clamp body 512 and into the groove 570, for example, between the inner sealing surface 526 and the inner sealing surface 536. For example, the probe assembly 540 may extend through the opening 513. The opening 513 may be located on the atmospheric (e.g., external environment 507) side of the clamp assembly 510, which does not interfere with the inner sealing surface 526 or the inner sealing surface 536. The input lead 542 may be attached to the input probe 544. The probe tip 546 may be electrically connected to the seal 560. For example, the probe tip 546 may abut the seal 560 (e.g., an outer surface of the seal 560). The input probe 544 (e.g., the probe tip 546) may be compliant as to not puncture or damage the seal 560 when making the electrical connection. For example, the input probe 544 (e.g., the probe tip 546) may include a spring loaded contact. Alternatively, the input probe 544 may be solid (e.g., non-compliant. The input probe 544 (e.g., the spring loaded contact) may be configured to compensate for mechanical interference between the seal 560 and the probe assembly 540, for example, which may be caused by compression of the fitting, an increase in seal CX geometry due to thermal expansion, tolerance stack up, and/or other reasons.

In examples, the output lead 552 may be configured to be electrically connected to the clamp assembly 510 (e.g., the clamp body 512). For example, the output lead 552 may abut a surface (e.g., internal surface) of the clamp body 512. In examples, the probe assembly 540 may be configured to remain spaced away from the seal 560 within the groove 570. For example, a sensor on the probe assembly 540 may perform measurements and/or readings (e.g., real-time measurements and/or readings) on the seal 560 within the groove 570. The probe assembly 540 may perform one or more calculations based on the measurements and/or readings.

The upper pipe portion 520 and the output lead 550 may be attached to the lower pipe portion 530. It should be appreciated that the input lead 542 and/or the output lead 550 may be attached to the pipe portions 520, 530 using alternative methods.

In the example shown in FIGS. 5A-5D, current may flow from the input lead 542, through the input probe 544, through the probe tip 546, through the seal 560, through the upper pipe portion 520 and/or the lower pipe portion 530, through the clamp body 512, through the output probe 552, and out of the output lead 550. The input probe 544 and the output probe 552 may include a conductive material. For example, the input probe 544 and the output probe 552 may include a stainless steel and/or aluminum. The clamp body 512 may include a conductive material. The centering ring 562 and the insulator 548 may include non-conductive materials. For example, the centering ring 562 may be made of PTFE and/or PEEK, the insulator 548 may be made of PTFE and/or PEEK, and/or the clamp assembly 510 may be made of PTFE and/or PEEK.

In the example shown in FIGS. 5A-5D, integrating the input probe 544, the output probe 552, and the insulator 548 may simplify integration into a mechanical sealing system. For example, an existing (e.g., installed) clamp (e.g., such as clamp assembly 510) may be modified to incorporate the probe assembly 540 such as using a press fit or threaded connection into the clamp. Other configurations of incorporating an input probe and output probe may require modification of two or more components of the system, including at least one pipe component, which can be difficult if made with a thin wall metal. Modification of just the clamp (e.g., such as the clamp assembly 510) may be advantageous considering the clamp is typically a cheaper and simpler component as compared to the pipe components, which can span various lengths.

The probe assembly 540 may be configured to perform wireless communications. For example, the probe assembly 540 may be Bluetooth-enabled. The probe assembly 540 may be configured to send one or more measurements and/or calculations associated with the seal 560 to another computing device. The seal 560 may be bonded. For example, an insulating adhesive or a conductive adhesive may be added to the sealing arrangement 500.

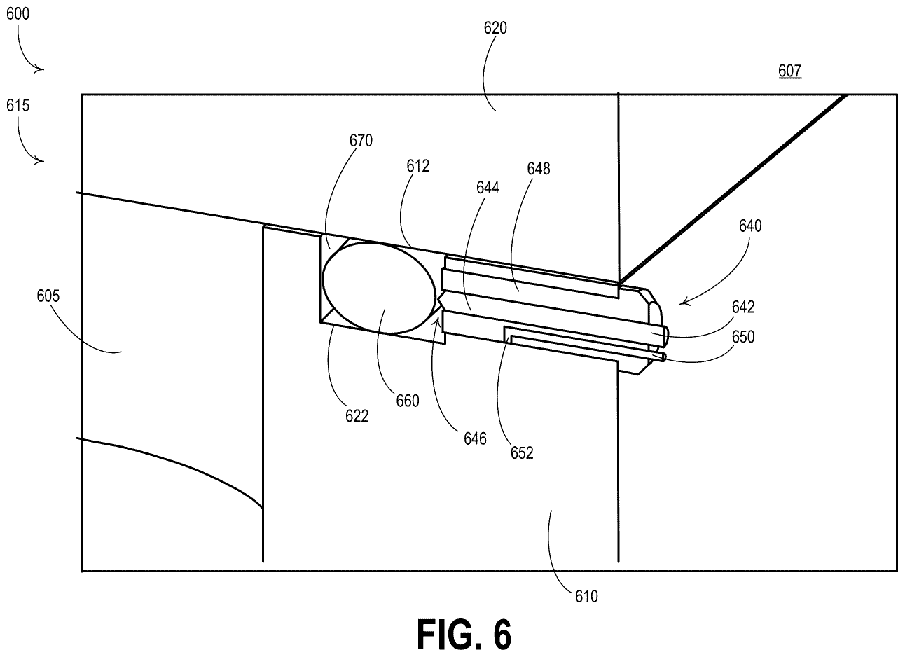

FIG. 6 depicts an example probe assembly 600. The probe assembly 600 may be configured to measure one or more properties (e.g., electrical properties) of a seal 660 (e.g., such as the seal 106 shown in FIG. 1A, the seal 154 shown in FIG. 1B, the seal 260 shown in FIGS. 2A-2B, the seal 360 shown in FIGS. 3A-3B, the seal 460 shown in FIGS. 4A-4C, and/or the seal 560 shown in FIGS. 5A-5D). The seal 660 may be configured to be installed between two body portions 610, 620 of a hardware assembly 615. The hardware assembly 615 may be a body and/or a housing. For example, the seal 660 may be configured to provide a seal between an upper body portion 620 and a lower body portion 610. The seal 660 may be an o-ring, a t-seal, a u-cup, an x-ring, a d-ring, a square ring, a wiper seal, etc. The seal 660 may have one or more varying electrical properties. The one or more varying electrical properties of the seal 660 may include resistance, capacitance, and/or inductance. For example, one or more electrical properties of the seal 660 may vary when the seal 660 is compressed by a force, when a current is applied to the seal 660, when the seal 660 is exposed to application conditions, when the seal 660 is chemically attacked, when the seal 660 is physically attacked, and/or when the seal 660 is exposed to a varying temperature.

The seal 660 may be a conductive seal. For example, the seal 660 may include one or more conductive materials having quantum tunneling composite effects. The probe assembly 600 may be configured to enable measurement of the seal 660, when the seal 660 remains installed between the body portions 620, 610. The probe assembly 600 may include an electrical probe, an acoustic probe, a piezoelectric probe, and/or a pressure differential probe. It should be appreciated that the probe assembly 600 is not limited to these examples and instead may include one or more other types of probes.

The upper body portion 620 may define a lower sealing surface 612. The lower sealing surface 612 may be a bottom surface of the upper body portion 620. The lower body portion 610 may define an upper sealing surface 622. The upper sealing surface 622 may be a top surface of the lower body portion 610.

An inner area 605 may be defined between the two body portions 620 and 610. The inner area 605 may be sealed from the external environment 607 by the seal 660. The lower body portion 610 and/or the upper body portion 620 may define a groove 670. The groove 670 may be configured to receive the seal 660. The seal 660 may be located between the upper sealing surface 622 and the lower sealing surface 612, for example, within the groove 670.

The probe assembly 640 may include an input lead 642 (e.g., such as the input lead 160 shown in FIG. 1B) and an output lead 650 (e.g., such as the output lead 162 shown in FIG. 1B). The probe assembly 640 may further include an insulator 648, an input probe 644, a probe tip 546, an output probe 652, and an output lead 650. The insulator 648 may be an insulating sleeve that surrounds at least a portion of the input probe 644 and the output probe 652. For example, the input probe 644 and the output probe 652 may be received within the insulator 648 such that the input probe 644 and the output probe 652 are electrically insulated from the body portion 610, 620. The insulator 648 may be configured to electrically isolate the input probe 644 from the output probe 652. The probe tip 646 may extend beyond the insulator 648.

The probe assembly 600 may be configured to extend through the lower body portion 620 or the upper body portion 610 and into the groove 670, for example, between the upper sealing surface 612 and the lower sealing surface 622. For example, the probe assembly 600 may extend from an atmospheric (e.g., external environment 607) side of the hardware assembly 615, which does not interfere with the upper sealing surface 612 or the lower sealing surface 622. The input lead 642 may be attached to the input probe 644. The probe tip 646 may be electrically connected to the seal 660. For example, the probe tip 646 may abut the seal 660 (e.g., an outer surface of the seal 660). The input probe 644 (e.g., the probe tip 646) may be compliant as to not puncture or damage the seal 660 when making the electrical connection. For example, the input probe 644 (e.g., the probe tip 646) may include a spring loaded contact. Alternatively, the input probe 644 may be solid (e.g., non-compliant. The input probe 644 (e.g., the spring loaded contact) may be configured to compensate for mechanical interference between the seal 660 and the probe assembly 600, for example, which may be caused by compression of the fitting, an increase in seal CX geometry due to thermal expansion, tolerance stack up, and/or other reasons.

The output probe 652 may be configured to be electrically connected to the hardware assembly 615 (e.g., the lower body portion 630). For example, the output probe 652 may abut a surface (e.g., internal surface) of the hardware assembly 615 (e.g., the lower body portion 630).

In the example shown in FIG. 6, current may flow from the input lead 642, through the input probe 644, through the probe tip 646, through the conductive seal 660, through the upper body portion 620 and/or the lower body portion 630, through the output probe 652, and out of the output lead 650. The input probe 644 and the output probe 652 may include a conductive material. For example, the input probe 644 and the output probe 652 may include a stainless steel, aluminum, copper, or another conductive material. The lower body portion 630 may include a conductive material.

In the example shown in FIG. 6, integrating the input probe 644, the output probe 652, and the insulator 648 may simplify integration into a mechanical sealing system. For example, an existing (e.g., installed) hardware assembly (e.g., such as hardware assembly 615) may be modified to incorporate the probe assembly 600 such as using a press fit or threaded connection into the clamp. Other configurations of incorporating an input probe and output probe may require modification of two or more components of the system, including at least one pipe component, which can be difficult if made with a thin wall metal.

The probe assembly 600 may be configured to perform wireless communications. For example, the probe assembly 600 may be Bluetooth-enabled. The probe assembly 600 may be configured to send one or more measurements and/or calculations associated with the seal 660 to another computing device.

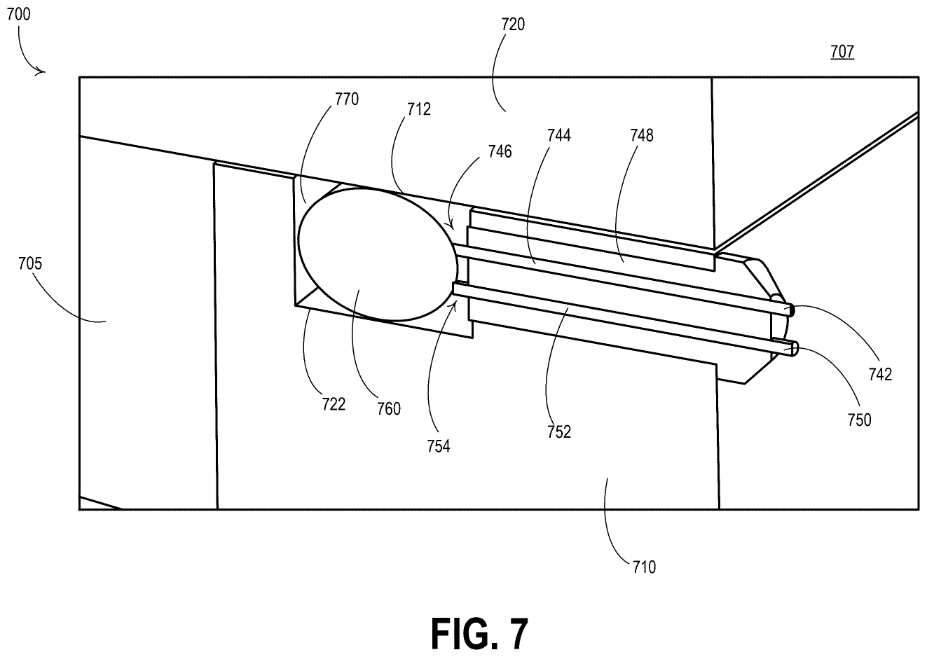

FIG. 7 depicts an example probe assembly 700. The probe assembly 700 may be configured to measure one or more electrical properties of a seal 760 (e.g., such as the seal 106 shown in FIG. 1A, the seal 154 shown in FIG. 1B, the seal 260 shown in FIGS. 2A-2B, the seal 360 shown in FIGS. 3A-3B, the seal 460 shown in FIGS. 4A-4C, the seal 560 shown in FIGS. 5A-5D, and/or the seal 660 shown in FIG. 6). The seal 760 may be configured to be installed between two body portions 710, 720 of a hardware assembly 715. For example, the seal 760 may be configured to provide a seal between an upper body portion 720 and a lower body portion 710. The seal 760 may be an o-ring, a t-seal, a u-cup, an x-ring, a d-ring, a square ring, a wiper seal, etc. The seal 760 may have one or more varying electrical properties. The one or more varying electrical properties of the seal 760 may include resistance, capacitance, and/or inductance. For example, one or more electrical properties of the seal 760 may vary when the seal 760 is compressed by a force, when a current is applied to the seal 760, when the seal 760 is exposed to application conditions, when the seal 760 is chemically attacked, when the seal 760 is physically attacked, and/or when the seal 760 is exposed to a varying temperature.

The seal 760 may be a conductive seal. For example, the seal 760 may include one or more conductive materials having quantum tunneling composite effects. The probe assembly 700 may be configured to enable measurement of the seal 760, when the seal 760 remains installed between the body portions 720, 710. The probe assembly 700 may include an electrical probe, an acoustic probe, a piezoelectric probe, and/or a pressure differential probe. It should be appreciated that the probe assembly 700 is not limited to these examples and instead may include one or more other types of probes.

The upper body portion 720 may define a lower sealing surface 712. The lower sealing surface 712 may be a bottom surface of the upper body portion 720. The lower body portion 710 may define an upper sealing surface 722. The upper sealing surface 722 may be a top surface of the lower body portion 710.

An inner area 705 may be defined between the two body portions 720 and 710. The inner area 705 may be sealed from the external environment 707 by the seal 760. The lower body portion 710 and/or the upper body portion 720 may define a groove 770. The groove 770 may be configured to receive the seal 760. The seal 760 may be located between the upper sealing surface 722 and the lower sealing surface 712, for example, within the groove 770.

The probe assembly 700 may include an input lead 742 (e.g., such as the input lead 160 shown in FIG. 1B) and an output lead 750 (e.g., such as the output lead 162 shown in FIG. 1B). The probe assembly 700 may further include an insulator 748, an input probe 744, an input probe tip 746, an output probe 752, an output probe tip 754, and an output lead 750. The insulator 748 may be an insulating sleeve that surrounds at least a portion of the input probe 744 and the output probe 752. For example, the input probe 744 and the output probe 752 may be received within the insulator 748 such that the input probe 744 and the output probe 752 are electrically insulated from the body portions 710, 720. The insulator 748 may be configured to electrically isolate the input probe 744 from the output probe 752. The input probe tip 746 and the output probe tip 754 may extend beyond the insulator 748.

The probe assembly 700 may be configured to extend through the lower body portion 710 or the upper body portion 720 and into the groove 770, for example, between the upper sealing surface 712 and the lower sealing surface 722. For example, the probe assembly 700 may extend from an atmospheric (e.g., the external environment 707) side of the hardware assembly 715, which does not interfere with the upper sealing surface 712 or the lower sealing surface 722. The input lead 742 may be attached to the input probe 744. The output lead 750 may be attached to the output prove 752. In examples, the input probe tip 746 and the output probe tip 754 may be electrically connected to the seal 760. For example, the input probe tip 746 and the output probe tip 754 may abut the seal 760 (e.g., an outer surface of the seal 760). The input probe 744 (e.g., the input probe tip 746) and/or the output probe 752 (e.g., the output probe tip 754) may be compliant as to not puncture or damage the seal 760 when making the electrical connection. For example, the input probe 744 (e.g., the input probe tip 746) and/or the output probe 752 (e.g., the output probe tip 754) may include a spring loaded contact. Alternatively, the input probe 744 and/or the output probe 752 may be solid (e.g., non-compliant). The input probe 744 (e.g., the spring loaded contact) and/or the output probe 752 (e.g., the spring loaded contact) may be configured to compensate for mechanical interference between the seal 760 and the probe assembly 700, for example, which may be caused by compression of the fitting, an increase in seal CX geometry due to thermal expansion, tolerance stack up, and/or other reasons.

In the example shown in FIG. 7, current may flow from the input lead 742, through the input probe 744, through the input probe tip 746, through the conductive seal 760, through the output probe tip 754, through the output probe 752, and out of the output lead 750. The input probe 744 and the output probe 752 may include a conductive material. For example, the input probe 744 and the output probe 752 may include a stainless steel, aluminum (e.g., an aluminum alloy), and/or copper (e.g., a copper alloy).

In the example shown in FIG. 7, integrating the input probe 744, the output probe 752, and the insulator 748 may simplify integration into a mechanical sealing system. For example, an existing (e.g., installed) hardware assembly (e.g., such as hardware assembly 715) may be modified to incorporate the probe assembly 700 such as using a press fit or threaded connection into the clamp. Other configurations of incorporating an input probe and output probe may require modification of two or more components of the system, including at least one pipe component, which can be difficult if made with a thin wall metal.

In examples, the input probe 744 and/or the output probe 752 may be configured to remain spaced away from the seal 760 within the groove 770. For example, one or more sensors on the input probe 744 and/or one or more sensors on the output probe 752 may perform measurements and/or readings (e.g., real-time measurements and/or readings) on the seal 760 within the groove 770. The input probe 744 and/or the output probe 752 may perform one or more calculations based on the measurements and/or readings.

The probe assembly 700 may be configured to perform wireless communications. For example, the probe assembly 700 may be Bluetooth-enabled. The probe assembly 700 may be configured to send one or more measurements and/or calculations associated with the seal 760 to another computing device.

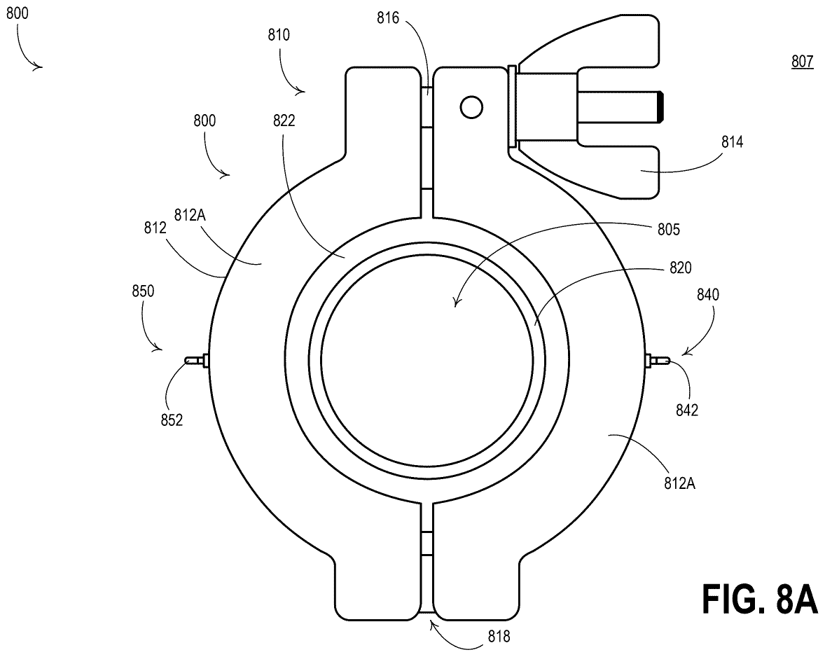

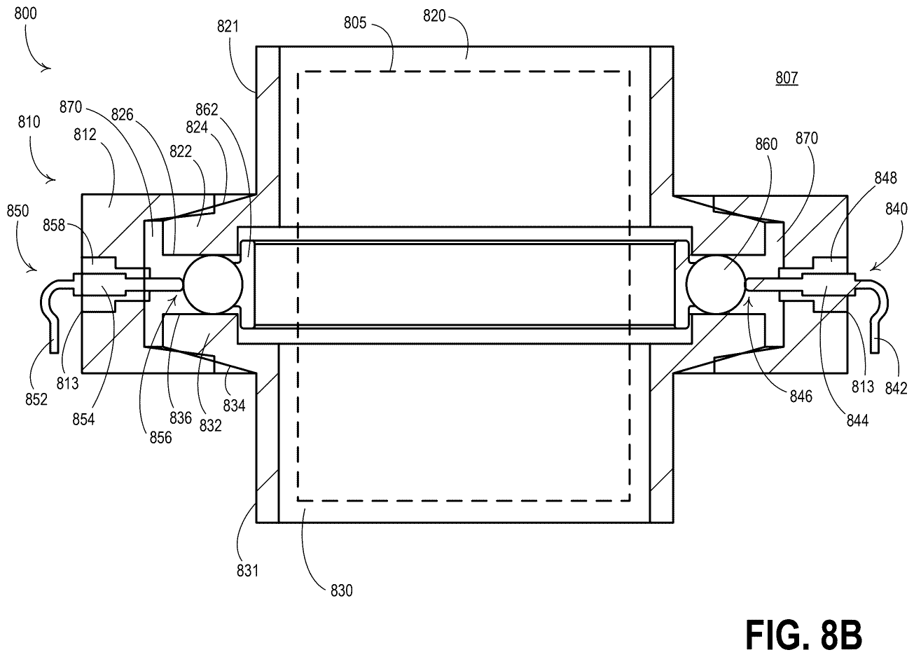

FIGS. 8A-8B depicts another example sealing arrangement 800. The sealing arrangement 800 may include a seal 860 (e.g., such as the seal 108 shown in FIG. 1A, the seal 154 shown in FIG. 1B, the seal 260 shown in FIGS. 2A-2B, the seal 360 shown in FIGS. 3A-3B, the seal 460 shown in FIGS. 4A-4C, the seal 560 shown in FIGS. 5A-5D, the seal 660 shown in FIG. 6, and/or the seal 760 shown in FIG. 7) and a centering ring 862. The centering ring 862 may be an inner gasket of the sealing arrangement 800. The seal 860 may be configured to be installed between two pipe portions 820, 830. For example, the seal 860 may be configured to provide a seal between an upper pipe portion 820 and a lower pipe portion 830. The seal 860 may be an o-ring, a t-seal, a u-cup, an x-ring, a d-ring, a square ring, a wiper seal, etc. The seal 860 may have one or more varying electrical properties. The one or more varying electrical properties of the seal 860 may include resistance, capacitance, and/or inductance. For example, one or more electrical properties of the seal 860 may vary when the seal 860 is compressed by a force, when a current is applied to the seal 860, when the seal 860 is exposed to application conditions, when the seal 860 is chemically attacked, when the seal 860 is physically attacked, and/or when the seal 860 is exposed to a varying temperature.

The seal 860 may be a conductive seal. For example, the seal 860 may include one or more conductive materials having quantum tunneling composite effects. The sealing arrangement 800 (e.g., the seal 860) may include one or more conductive materials having quantum tunneling composite effects. The sealing arrangement 800 may be configured to enable measurement of the seal 860, when the seal 860 remains installed between the pipe portions 820, 830.

Additionally or alternatively, the 860 may incorporate electrodes. The electrodes may be incorporated into the seal 860, for example, to connect to an elastomer of the seal 860. For example, the electrodes may be stuck into a vulcanized elastomer or molded into the elastomer of the seal 860. In examples, the electrodes may be fixed to the surface of the elastomer of the seal 860.

The upper pipe portion 820 may define a first flange 822, for example, at a distal end of the upper pipe portion 820. The first flange 822 may define an outer surface 824 and a sealing inner surface 826. The inner sealing surface 826 may be a seal contact surface of the upper pipe portion 820. The lower pipe portion 830 may define a first flange 832, for example, at a distal end of the lower pipe portion 830. The first flange 832 may define an outer surface 834 and an inner sealing surface 836. The inner sealing surface 836 may be a seal contact surface of the lower pipe portion 830.

The sealing arrangement 800 may include a clamp assembly 810. The clamp assembly 810 may be attached to the two pipe portions 820, 830. The clamp assembly 810 may abut the upper pipe portion 820 and the lower pipe portion 830 to clamp together the pipe portions 820, 830. For example, the clamp assembly 810 may be configured to abut the first flange 822 (e.g., the outer surface 824 of the first flange 822) and the second flange 832 (e.g., the outer surface 834 of the second flange 832). The clamp assembly 810 may be a Klein Flancsche (KF) vacuum fitting clamp. The clamp assembly 810 may include a clamp body 812, a wing nut 814, a threaded post 816, and a pivot joint 818. The clamp body 812 may define an opening 813. The clamp body 812 may define a first body portion 812A and a second body portion 812B. The first body portion 812A and the second body portion 812B may be configured to pivot about the pivot joint 818, for example, to secure the upper pipe portion 820 to the lower pipe portion 830. For example, the first body portion 812A and the second body portion 812B may be moved apart to be located over the first flange 822 and the second flange 832. The first body portion 812A and the second body portion 812B may be moved toward each other to enable the wing nut 814 to be installed on the threaded post 816. When the wing nut 814 is installed on the threaded post 816, the wing nut 814 may be tightened on the threaded post 816 to move the first body portion 812A and the second body portion 812B closer to each other around the first flange 822 and the second flange 832. As the wing nut 814 is tightened, the first body portion 812A may abut the outer surface 824 of the first flange 822 and the second body portion 812B may abut the outer surface 834 of the second flange 832, for example, to clamp the two pipe portions 820, 830 together with the conductive seal 860 between the two pipe portions 820, 830.

When the two pipe portions 820, 830 are clamped together, an inner pipe area 805 may be defined by the two pipe portions 820, 830. The inner pipe area 805 may be sealed from the external environment 807 by the electrically conductive seal assembly 800. The clamp assembly 810 and the two pipe portions 820, 830 may define a groove 870. The groove 870 may be defined between the clamp body 812, the first flange 822 (e.g., the inner sealing surface 826 of the first flange 822), and the second flange 832 (e.g., the inner sealing surface 836 of the second flange 832). The groove 870 may represent the open volume area configured to enable separation of the inner pipe area 805 from the external environment 807. The seal 860 may be located within the groove 870, for example, between the inner sealing surface 826 of the first flange 822 and the inner sealing surface 836 of the second flange 832.

The sealing arrangement 800 may include a first probe assembly 840 (e.g., an input probe assembly) and a second probe assembly 850 (e.g., an output probe assembly). The first probe assembly 840 and the second probe assembly 850 may be configured such as the probe assembly 540 shown in FIG. 5C, the probe assembly 600 shown in FIG. 6, and/or the probe assembly 700 shown in FIG. 7). The first probe assembly 840 and the second probe assembly 850 may extend through the clamp body 812 (e.g., approximately 180 degrees apart from each other). The first probe assembly 840 may include an input lead 842 (e.g., such as the input lead 160 shown in FIG. 1B), an insulator 848, and an input probe 844. The input probe 844 may be an electrical probe, an acoustic probe, a piezoelectric probe, and/or a pressure differential probe. It should be appreciated that the input probe 844 is not limited to these examples and instead may be another type of probe. The input probe 844 may define an input probe tip 846 at a distal end of the input probe 844. The insulator 848 may be an insulating sleeve that surrounds at least a portion of the input probe 844. For example, the input probe 844 may be received within the insulator 848. The input probe tip 846 may extend beyond the insulator 848. The second probe assembly 850 may include an output lead 852 (e.g., such as the output lead 162 shown in FIG. 1B), an insulator 858, and an output probe 852. The output probe 854 may be an electrical probe, an acoustic probe, a piezoelectric probe, and/or a pressure differential probe. It should be appreciated that the output probe 854 is not limited to these examples and instead may be another type of probe. The output probe 854 may define an output probe tip 856 at a distal end of the output probe 854. The insulator 858 may be an insulating sleeve that surrounds at least a portion of the output probe 854. For example, the output probe 854 may be received within the insulator 858. The output probe tip 856 may extend beyond the insulator 858. The first probe assembly 840 and the second probe assembly 850 may be configured to extend through the clamp body 812 and into the groove 870, for example, between the inner sealing surface 826 of the first flange 822 and the inner sealing surface 836 of the second flange 832. The input lead 842 may be attached to the input probe 844.

In examples, the input probe tip 846 may be electrically connected to the seal 860. For example, the probe tip 846 may abut the seal 860 (e.g., an outer surface of the seal 860). The input probe 844 (e.g., the input probe tip 846) may be compliant as to not puncture or damage the seal 860 when making the electrical connection. For example, the input probe 844 (e.g., the input probe tip 846) may include a spring loaded contact. The input probe 844 (e.g., the spring loaded contact) may be configured to compensate for mechanical interference between the seal 860 and the probe assembly 840, for example, which may be caused by compression of the fitting, an increase in seal CX geometry due to thermal expansion, tolerance stack up, and/or other reasons.

The output probe tip 856 may be electrically connected to the seal 860. For example, the output probe tip 856 may abut the seal 860 (e.g., an outer surface of the seal 860). The output probe 854 (e.g., the output probe tip 856) may be compliant as to not puncture or damage the seal 860 when making the electrical connection. For example, the output probe 854 (e.g., the output probe tip 856) may include a spring loaded contact. The output probe 854 (e.g., the spring loaded contact) may be configured to compensate for mechanical interference between the seal 860 and the second probe assembly 850, for example, which may be caused by compression of the fitting, an increase in seal CX geometry due to thermal expansion, tolerance stack up, and/or other reasons.

In the example shown in FIGS. 8A-8B, the input lead 842 and the output lead 852 may be used to circumferentially measure one or more electrical properties of the seal 860. For example, current may flow from the input lead 842, through the input probe 844, through the seal 860, through the output probe 854, and out of the output lead 852. The input probe 844 and the output probe 854 may include a conductive material. For example, the input probe 844 and the output probe 854 may include a stainless steel, aluminum (e.g., an aluminum alloy), and/or copper (e.g., a copper alloy). The centering ring 862 and the clamp assembly 810 may be electrically isolated from the seal 860.

In examples, the first probe assembly 840 and/or the second probe assembly 850 may be configured to remain spaced away from the seal 860 within the groove 870. For example, one or more sensors on the first probe assembly 840 and/or one or more sensors on the second probe assembly 850 may perform measurements and/or readings (e.g., real-time measurements and/or readings) on the seal 860 within the groove 870. The first probe assembly 840 and/or the second probe assembly 850 may perform one or more calculations based on the measurements and/or readings.

The first probe assembly 840 and the second probe assembly 850 may be configured to perform wireless communications. For example, the first probe assembly 840 and/or the second probe assembly 850 may be Bluetooth-enabled. The first probe assembly 840 and/or the second probe assembly 850 may be configured to send one or more measurements and/or calculations associated with the seal 860 to another computing device.

The seal 860 may be bonded. For example, an insulating adhesive or a conductive adhesive may be added to the sealing arrangement 800. Resistance of the seal 860 (e.g., when measured circumferentially) may increase as the seal 860 is compressed. For example, the conductive path of the sealing arrangement 800 may increase in resistivity as the seal 860 is compressed.

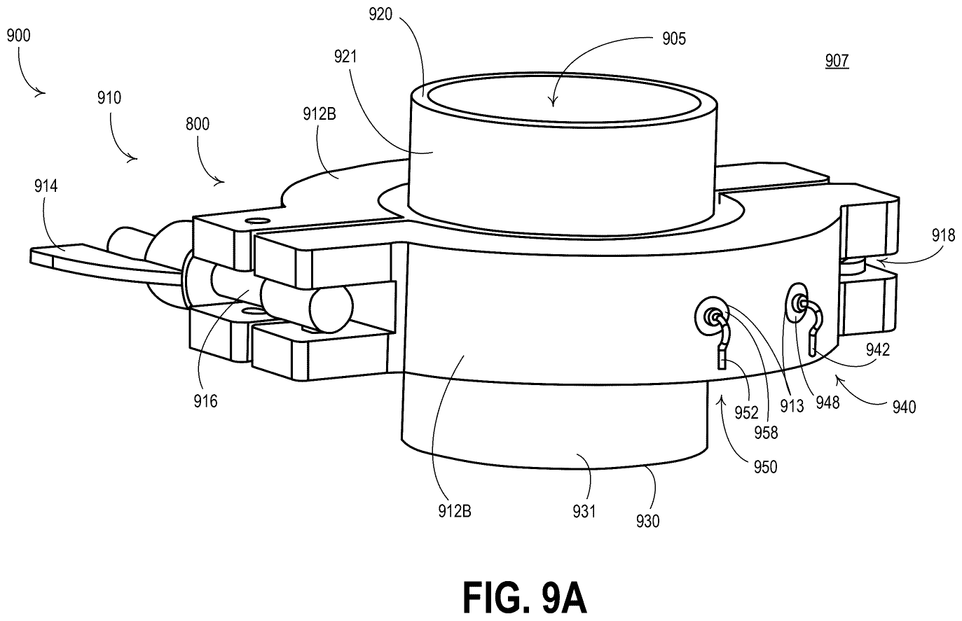

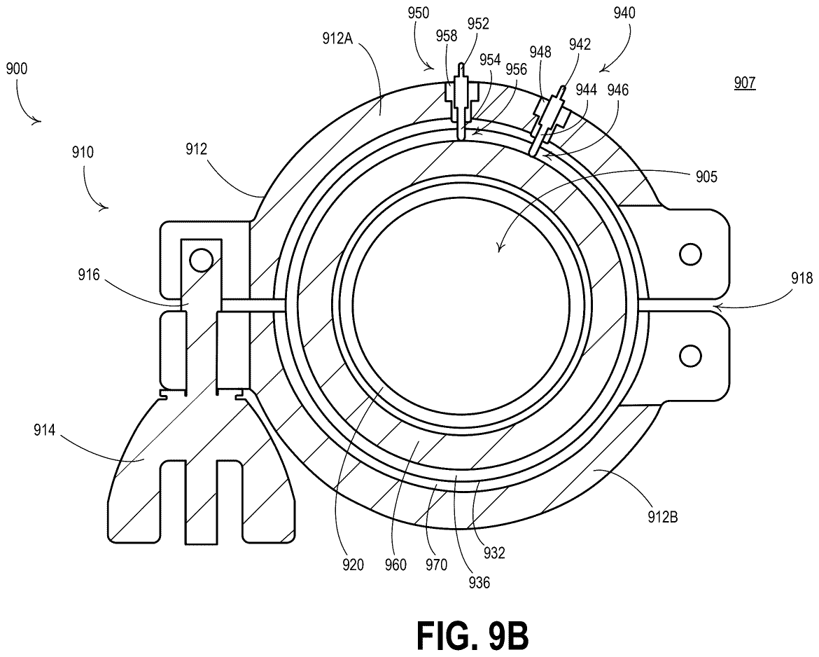

FIGS. 9A-9B depicts another example sealing arrangement 900. The sealing arrangement 900 may include a seal 960 (e.g., such as the seal 108 shown in FIG. 1A, the seal 154 shown in FIG. 1B, the seal 260 shown in FIGS. 2A-2B, the seal 360 shown in FIGS. 3A-3B, the seal 460 shown in FIGS. 4A-4C, the seal 560 shown in FIGS. 5A-5D, the seal 660 shown in FIG. 6, the seal 760 shown in FIG. 7, and/or the seal 860 shown in FIGS. 8A-8B) and centering ring 962. The centering ring 962 may be an inner gasket of the sealing arrangement 900. The sealing arrangement 900 may be configured to be installed between two pipe portions 920, 930. For example, the seal 960 may be configured to provide a seal between an upper pipe portion 920 and a lower pipe portion 930. The seal 960 may be an o-ring, a t-seal, a u-cup, an x-ring, a d-ring, a square ring, a wiper seal, etc. The seal 960 may have one or more varying electrical properties. The one or more varying electrical properties of the seal 960 may include resistance, capacitance, and/or inductance. For example, one or more electrical properties of the seal 960 may vary when the seal 960 is compressed by a force, when a current is applied to the seal 960, when the seal 960 is exposed to application conditions, when the seal 960 is chemically attacked, when the seal 960 is physically attacked, and/or when the seal 960 is exposed to a varying temperature.

The seal 960 may be a conductive seal. For example, the seal 960 may include one or more conductive materials having quantum tunneling composite effects. The sealing arrangement 900 (e.g., the seal 960) may include one or more conductive materials having quantum tunneling composite effects. The sealing arrangement 900 may be configured to enable measurement of the seal 960, when the seal 960 remains installed between the pipe portions 920, 930.

Additionally or alternatively, the seal 960 may incorporate electrodes. The electrodes may be incorporated into the seal 960, for example, to connect to an elastomer of the seal 960. For example, the electrodes may be stuck into a vulcanized elastomer or molded into the elastomer of the seal 960. In examples, the electrodes may be fixed to the surface of the elastomer of the seal 960.

The upper pipe portion 920 may define a first flange 922, for example, at a distal end of the upper pipe portion 920. The first flange 922 may define an outer surface 924 and a sealing inner surface 926. The inner sealing surface 926 may be a seal contact surface of the upper pipe portion 920. The lower pipe portion 930 may define a first flange 932, for example, at a distal end of the lower pipe portion 930. The first flange 932 may define an outer surface 934 and an inner sealing surface 936. The inner sealing surface 936 may be a seal contact surface of the lower pipe portion 930.

The sealing arrangement 900 may include a clamp assembly 910. The clamp assembly 910 may be attached to the two pipe portions 920, 930. The clamp assembly 910 may abut the upper pipe portion 920 and the lower pipe portion 930 to clamp together the pipe portions 920, 930. For example, the clamp assembly 910 may be configured to abut the first flange 922 (e.g., the outer surface 924 of the first flange 922) and the second flange 932 (e.g., the outer surface 934 of the second flange 932). The clamp assembly 910 may be a Klein Flancsche (KF) vacuum fitting clamp. The clamp assembly 910 may include a clamp body 912, a wing nut 914, a threaded post 916, and a pivot joint 918. The clamp body 912 may define an opening 913. The clamp body 912 may define a first body portion 912A and a second body portion 912B. The first body portion 912A and the second body portion 912B may be configured to pivot about the pivot joint 918, for example, to secure the upper pipe portion 920 to the lower pipe portion 930. For example, the first body portion 912A and the second body portion 912B may be moved apart to be located over the first flange 922 and the second flange 932. The first body portion 912A and the second body portion 912B may be moved toward each other to enable the wing nut 914 to be installed on the threaded post 916. When the wing nut 914 is installed on the threaded post 916, the wing nut 914 may be tightened on the threaded post 916 to move the first body portion 912A and the second body portion 912B closer to each other around the first flange 922 and the second flange 932. As the wing nut 914 is tightened, the first body portion 912A may abut the outer surface 924 of the first flange 922 and the second body portion 912B may abut the outer surface 934 of the second flange 932, for example, to clamp the two pipe portions 920, 930 together with the conductive seal 960 between the two pipe portions 920, 930.

When the two pipe portions 920, 930 are clamped together, an inner pipe area 905 may be defined by the two pipe portions 920, 930. The inner pipe area 905 may be sealed from the external environment 907 by the seal 960. The clamp assembly 910 and the two pipe portions 920, 930 may define a groove 970. The groove 970 may be defined between the clamp body 912, the first flange 922 (e.g., the inner sealing surface 926 of the first flange 922), and the second flange 932 (e.g., the inner sealing surface 936 of the second flange 932). The groove 970 may represent the open volume area configured to enable separation of the inner pipe area 905 from the external environment 907. The seal 960 may be located within the groove 970, for example, between the inner sealing surface 926 and the inner sealing surface 936.

The sealing arrangement 900 may include a first probe assembly 940 (e.g., an input probe assembly) and a second probe assembly 950 (e.g., an output probe assembly). The first probe assembly 940 and the second probe assembly 950 may be configured such as the probe assembly 540 shown in FIG. 5C, the probe assembly 600 shown in FIG. 6, the probe assembly 700 shown in FIG. 7, the first probe assembly 840 shown in FIGS. 8A-8B, and/or the second probe assembly 850 shown in FIGS. 8A-8B). The first probe assembly 940 and the second probe assembly 950 may extend through the clamp body 912 (e.g., proximate to each other). The openings 913 in the clamp body 910 may be proximate to one another. For example, the first probe assembly 940 and the second probe assembly 950 may extend through the same clamp body portion (e.g., such as clamp body 912A). The first probe assembly 940 may include an input lead 942 (e.g., such as the input lead 160 shown in FIG. 1B), an insulator 948, and an input probe 944. The input probe 944 may be an electrical probe, an acoustic probe, a piezoelectric probe, and/or a pressure differential probe. It should be appreciated that the input probe 944 is not limited to these examples and instead may be another type of probe. The input probe 944 may define an input probe tip 946 at a distal end of the input probe 944. The insulator 948 may be an insulating sleeve that surrounds at least a portion of the input probe 944. For example, the input probe 944 may be received within the insulator 948. The input probe tip 946 may extend beyond the insulator 948.

The second probe assembly 950 may include an output lead 952 (e.g., such as the output lead 162 shown in FIG. 1B), an insulator 958, and an output probe 952. The output probe 954 may be an electrical probe, an acoustic probe, a piezoelectric probe, and/or a pressure differential probe. It should be appreciated that the output probe 954 is not limited to these examples and instead may be another type of probe. The output probe 954 may define an output probe tip 956 at a distal end of the output probe 954. The insulator 958 may be an insulating sleeve that surrounds at least a portion of the output probe 954. For example, the output probe 954 may be received within the insulator 958. The output probe tip 956 may extend beyond the insulator 958. The first probe assembly 940 and the second probe assembly 950 may be configured to extend through the clamp body 912 and into the groove 970, for example, between the inner sealing surface 926 and the inner sealing surface 936. The input lead 942 may be attached to the input probe 944.

In examples, the input probe tip 946 may be electrically connected to the seal 960. For example, the probe tip 946 may abut the seal 960 (e.g., an outer surface of the seal 960). The input probe 944 (e.g., the input probe tip 946) may be compliant as to not puncture or damage the seal 960 when making the electrical connection. For example, the input probe 944 (e.g., the input probe tip 946) may include a spring loaded contact. The input probe 944 (e.g., the spring loaded contact) may be configured to compensate for mechanical interference between the seal 960 and the probe assembly 940, for example, which may be caused by compression of the fitting, an increase in seal CX geometry due to thermal expansion, tolerance stack up, and/or other reasons.

In examples, the output probe tip 956 may be electrically connected to the seal 960. For example, the output probe tip 956 may abut the seal 960 (e.g., an outer surface of the seal 960). The output probe 954 (e.g., the output probe tip 956) may be compliant as to not puncture or damage the seal 960 when making the electrical connection. For example, the output probe 954 (e.g., the output probe tip 956) may include a spring loaded contact. The output probe 954 (e.g., the spring loaded contact) may be configured to compensate for mechanical interference between the seal 960 and the second probe assembly 950, for example, which may be caused by compression of the fitting, an increase in seal CX geometry due to thermal expansion, tolerance stack up, and/or other reasons.

In the example shown in FIGS. 9A-9B, the input lead 942 and the output lead 952 may be used to circumferentially measure one or more electrical properties of the seal 960. For example, current may flow from the input lead 942, through the input probe 944, through the seal 960, through the output probe 954, and out of the output lead 952. The input probe 944 and the output probe 954 may include a conductive material. For example, the input probe 944 and the output probe 954 may include a stainless steel, aluminum (e.g., an aluminum alloy), and/or copper (e.g., a copper alloy). The centering ring 962 and the clamp assembly 910 may be electrically isolated from the seal 960.

In examples, the first probe assembly 940 and/or the second probe assembly 950 may be configured to remain spaced away from the seal 960 within the groove 970. For example, one or more sensors on the first probe assembly 940 and/or one or more sensors on the second probe assembly 950 may perform measurements and/or readings (e.g., real-time measurements and/or readings) on the seal 960 within the groove 970. The first probe assembly 940 and/or the second probe assembly 950 may perform one or more calculations based on the measurements and/or readings.

The first probe assembly 940 and the second probe assembly 950 may be configured to perform wireless communications. For example, the first probe assembly 940 and/or the second probe assembly 950 may be Bluetooth-enabled. The first probe assembly 940 and/or the second probe assembly 950 may be configured to send one or more measurements and/or calculations associated with the seal 960 to another computing device.

The seal 960 may be bonded. For example, an insulating adhesive or a conductive adhesive may be added to the sealing arrangement 900. Resistance of the seal 960 (e.g., when measured circumferentially) may increase as the seal 960 is compressed. For example, the conductive path of the sealing arrangement 900 may increase in resistivity as the seal 960 is compressed.

It should be appreciated that a seal (e.g., such as the seal 108 shown in FIG. 1A, the seal 154 shown in FIG. 1B, the seal 260 shown in FIGS. 2A-2B, the seal 360 shown in FIGS. 3A-3B, the seal 460 shown in FIGS. 4A-4C, the seal 560 shown in FIGS. 5A-5D, and/or the seal 660 shown in FIG. 6, the seal 760 shown in FIG. 7, the seal 860 shown in FIGS. 8A-8B, and/or the seal 960 shown in FIGS. 9A-9B) as described herein may additionally or alternatively incorporate a sacrificial piece of conductive material which changes conductivity as material wears away or completely breaks contact (normally closed switch) and/or incorporate compressible features molded therein which create zones of conductivity within a single seal.

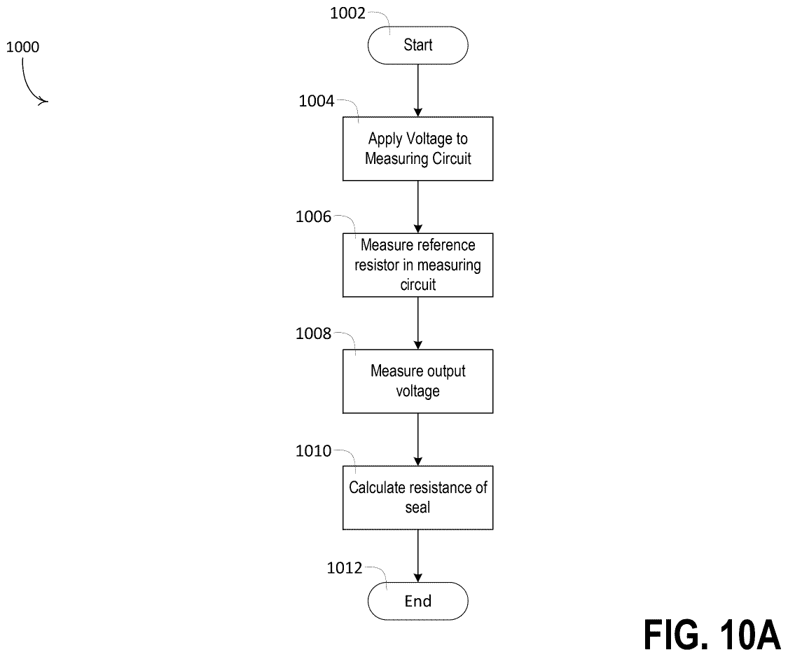

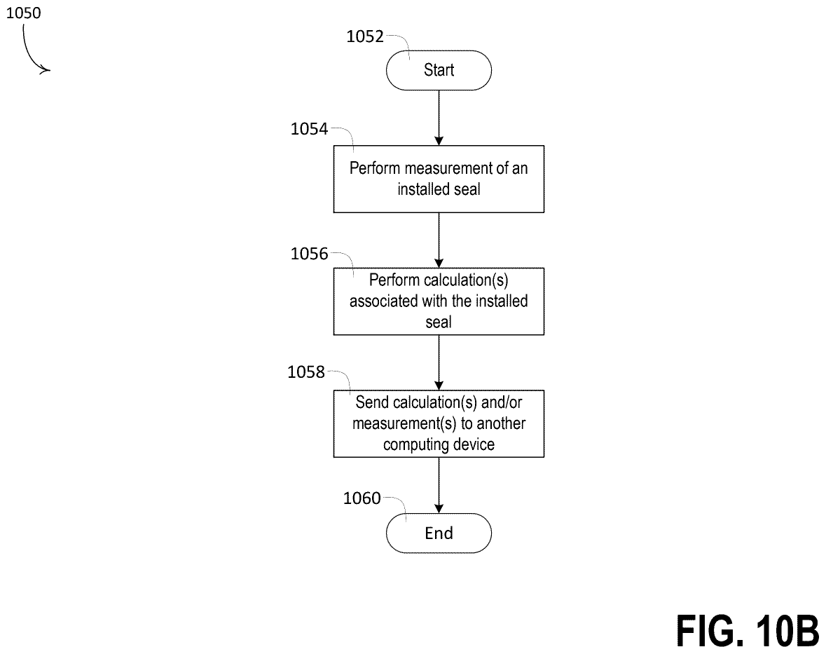

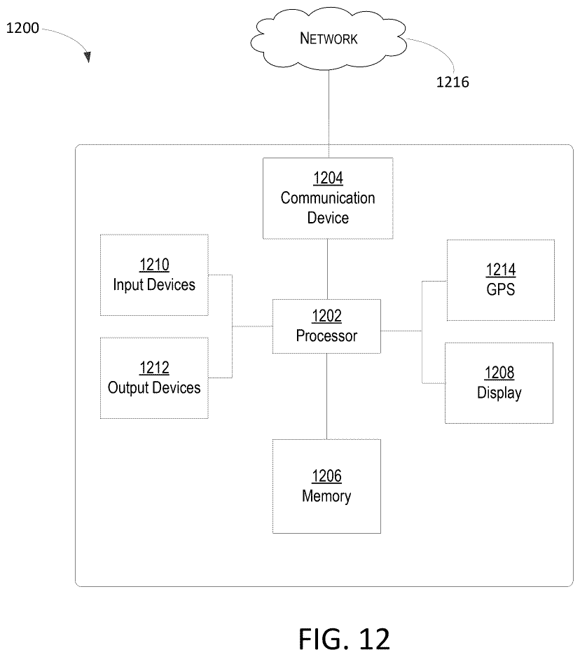

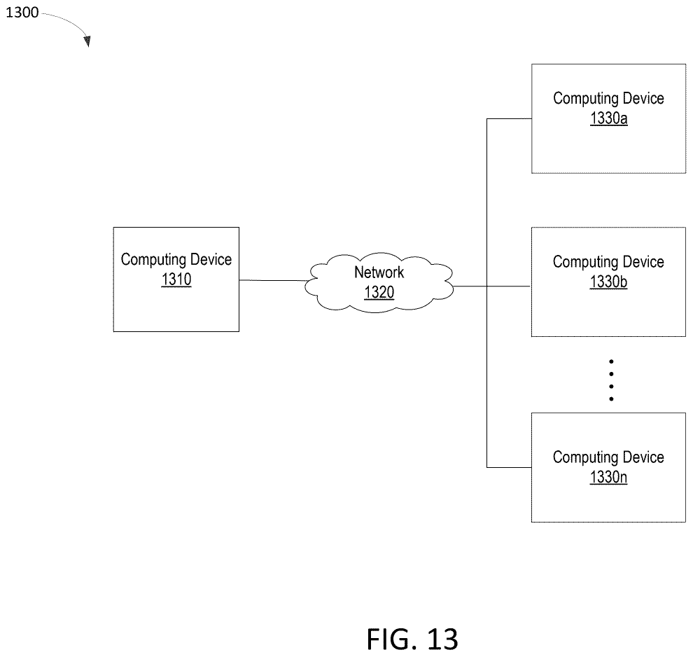

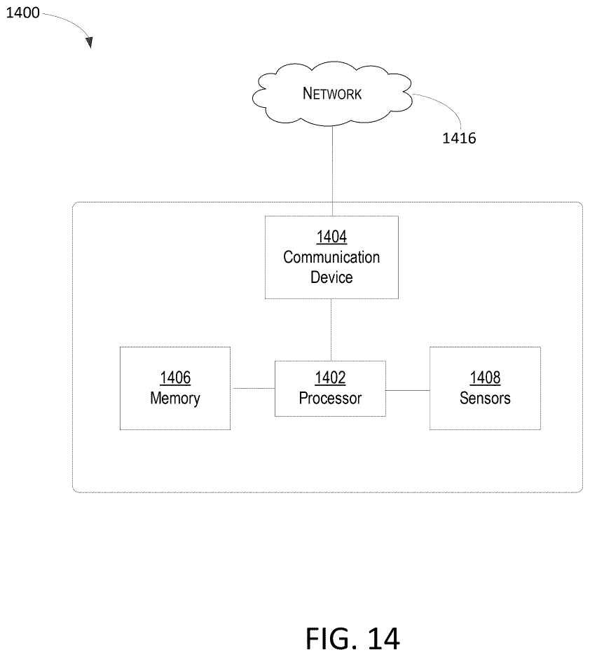

FIG. 10A is a flowchart of an example method 1000 that may be implemented by one or more computing devices (e.g., such as the computing device 1200 shown in FIG. 12, the computing devices 1330a-1330n shown in FIG. 13, and/or the probe assembly 1400 shown in FIG. 14) to measure one or more electrical properties of an installed seal. For example, the method 1000, or portions thereof, may enable real-time measurement of an installed seal. The method 1000, or portions thereof, may be performed to enable determination of a sealing performance, a remaining useful life, and/or a maintenance timeline of a seal (e.g., such as the seal 108 shown in FIG. 1A, the seal 154 shown in FIG. 1B, the seal 260 shown in FIGS. 2A-2B, the seal 360 shown in FIGS. 3A-3B, the seal 460 shown in FIGS. 4A-4C, the seal 500 shown in FIGS. 5A-5D, the seal 860 shown in FIGS. 8A-8B, and/or the seal 960 shown in FIGS. 9A-9B). The method 1000, or portions thereof, may be performed at a single computing device or may be distributed across multiple computing devices (e.g., multiple servers and/or a user device). The method 1000 may comprise instructions that may be stored in memory as computer-readable or machine-readable storage media that may be executed by the one or more computing devices for executing the method 1000. The method 1000, or portions thereof, may optimize lifetime of seals, reduce consumable waste, increase equipment uptime, improve overall equipment effectiveness (OEE) and other manufacturing process metrics, improve safety, and/or reduce unplanned downtime.

The method 1000 may start, at 1002, when a user computing device (e.g., such as the computing device 1200 and/or the computing device 1310 shown in FIG. 13) initiates a measurement process. For example, the user computing device may be configured to periodically initiate the measurement process (e.g., according to a pre-determined schedule). In examples, the user computing device may initiate the measurement process on demand, for example, in response to selection by a user of the user computing device.

At 1004, a voltage may be applied to a measuring circuit (e.g., such as the seal measuring circuit 150 shown in FIG. 1B). When the voltage is applied to the measuring circuit, a current may flow through the measuring circuit. For example, the current may flow through the seal.

At 1006, a reference resistor in the measuring circuit may be measured. At 1008, an output voltage of the measuring circuit may be measured.

At 1010, a resistance of the seal may be calculated. For example, the resistance of the seal may be determined by comparing the input voltage, the output voltage, and the measured resistance of the reference resistor. For example, the resistance of the seal may be determined using Equation 1. The resistance of the seal, calculated at 1010, may be stored in memory (e.g., such as memory 1206 shown in FIG. 12 and/or memory 1406 shown in FIG. 14). The method 1000 may be repeated, periodically according to a pre-determined schedule, and/or on-demand in response to being triggered. The method 1000, may end, at 1012.

FIG. 10B is a flowchart of an example method 1050 that may be implemented by one or more computing devices (e.g., such as the computing device 1200 shown in FIG. 12, the computing devices 1330a-1330n shown in FIG. 13, and/or the probe assembly 1400 shown in FIG. 14) to measure one or more electrical properties of an installed seal. For example, the method 1050, or portions thereof, may enable real-time measurement of an installed seal. The method 1050, or portions thereof, may be performed to enable determination of a sealing performance, a remaining useful life, and/or a maintenance timeline of a seal (e.g., such as the seal 108 shown in FIG. 1A, the seal 154 shown in FIG. 1B, the seal 260 shown in FIGS. 2A-2B, the seal 360 shown in FIGS. 3A-3B, the seal 460 shown in FIGS. 4A-4C, the seal 500 shown in FIGS. 5A-5D, the seal 860 shown in FIGS. 8A-8B, and/or the seal 960 shown in FIGS. 9A-9B). The method 1050, or portions thereof, may be performed at a single computing device or may be distributed across multiple computing devices (e.g., multiple servers and/or a user device). The method 1050 may comprise instructions that may be stored in memory as computer-readable or machine-readable storage media that may be executed by the one or more computing devices for executing the method 1050. The method 1050, or portions thereof, may optimize lifetime of seals, reduce consumable waste, increase equipment uptime, improve overall equipment effectiveness (OEE) and other manufacturing process metrics, improve safety, and/or reduce unplanned downtime.

The method 1050 may start, at 1052, when a probe assembly (e.g., one or more sensors of the probe assembly) initiates a measurement process of an installed seal. For example, the one or more sensors may be configured to periodically initiate the measurement process (e.g., according to a pre-determined schedule). In examples, the one or more sensors may initiate the measurement process on demand, for example, in response to selection by a user of a user computing device that is communication with the one or more sensors.

At. 1054, the one or more sensors may perform a measurement and/or a reading of the installed seal. The measurement and/or reading may be associated with an electrical property (e.g., resistance, inductance, capacitance). The measurement and/or reading may be associated with a pressure, a humidity, a temperature, etc.

At 1056, the probe assembly (e.g., the one or more sensors) may perform one or calculations associated with the installed seal. The one or more calculations may be performed based on the measurement(s) and/or reading(s). The one or more calculations may include one or more performance metrics associated with the installed seal, for example, such as a level of compression, a level of compressive force, and/or an erosion state associated with the seal.

At 1058, the probe assembly may send the one or more calculations, measurements, and/or readings to another computing device, for example, using Bluetooth, Zigbee, WiFi, etc. The one or more calculations, measurements, and/or readings may be stored in memory (e.g., such as the memory 1406 shown in FIG. 14). The method 1050 may be repeated, periodically according to a pre-determined schedule, and/or on-demand in response to being triggered. The method 1050, may end, at 1060.

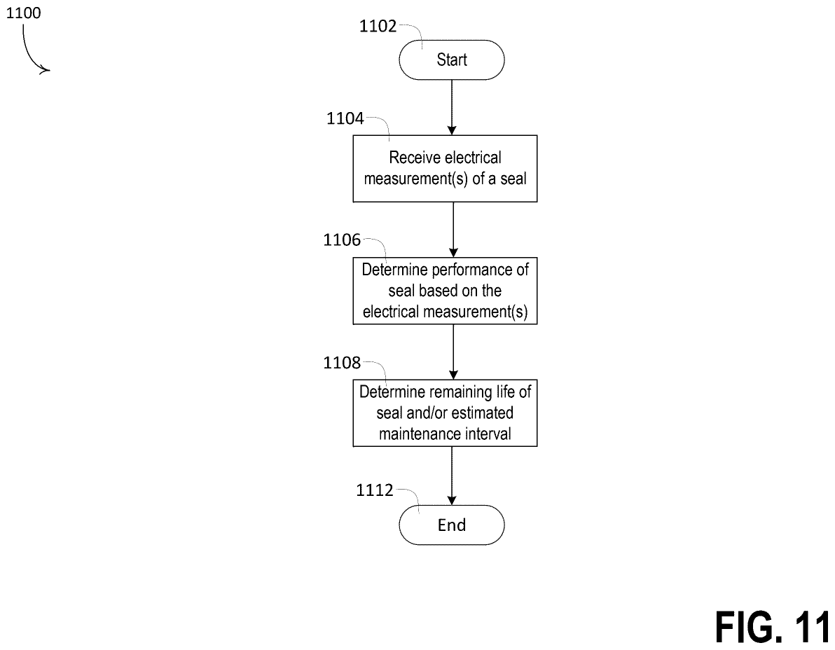

FIG. 11 is a flowchart of an example method 1100 that may be implemented by one or more computing devices (e.g., such as the computing device 1200 shown in FIG. 12, the computing devices 1330a-1330n shown in FIG. 13, and/or the probe assembly 1400 shown in FIG. 14) to process one or more measured electrical properties of an installed seal. The method 1100, or portions thereof, may result in determination of one or more electrical measurements of the installed seal that may correlate to process parameters used in semiconductor manufacturing. For example, the resistance of the seal may indicate the presence of elevated temperature in the process. The one or more electrical measurements may apply to a number of additional process parameters (e.g., in place of or in addition to the presence of an elevated temperature). The method 1100, or portions thereof, may provide additional information to the end user and transcend a predictive maintenance use case.

The method 1100, or portions thereof, may be performed to enable determination of a sealing performance, a remaining useful life, and/or a maintenance timeline of a seal (e.g., such as the conductive seal 108 shown in FIG. 1A, the seal 154 shown in FIG. 1B, the seal 260 shown in FIGS. 2A-2B, the seal 360 shown in FIGS. 3A-3B, the seal 460 shown in FIGS. 4A-4C, the seal 500 shown in FIGS. 5A-5D, the seal 860 shown in FIGS. 8A-8B, and/or the seal 960 shown in FIGS. 9A-9B). The method 1100, or portions thereof, may be performed at a single computing device or may be distributed across multiple computing devices (e.g., multiple servers and/or a user device). The method 1100 may comprise instructions that may be stored in memory as computer-readable or machine-readable storage media that may be executed by the one or more computing devices for executing the method 1100. The method 1100, or portions thereof, may optimize lifetime of seals, reduce consumable waste, increase equipment uptime, improve overall equipment effectiveness (OEE) and other manufacturing process metrics, improve safety, and/or reduce unplanned downtime.

The method 1100 may start, at 1102, when a user computing device (e.g., such as the computing device 1200, the computing device 1310 shown in FIG. 13, and/or the probe assembly 1400 shown in FIG. 14) initiates a measurement process. For example, the user computing device may be configured to periodically initiate the measurement process (e.g., according to a pre-determined schedule). In examples, the user computing device may initiate the measurement process on demand, for example, in response to selection by a user of the user computing device.

At 1104, the user computing device may receive one or more electrical measurements of the seal. The one or more electrical measurements may include a resistance, an inductance, a capacitance, etc.

At 1106, the user computing device may determine one or more performance metrics such as a level of compression, a level of compressive force, and/or an erosion state associated with the seal. For example, the user computing device may determine, at 1106, an estimated performance (e.g., sealing performance) of the seal based on the one or more electrical measurements received at 1104. The user computing device may correlate the one or more electrical measurements with a pre-determined sealing performance trend associated with the specific material of the seal. For example, an electrical property response of the seal may be related to the geometric shape of the seal. When the geometric shape of the seal changes from a baseline shape, the user computing device may determine a seal erosion from chemistry and/or a deformed state of the seal. Additionally or alternatively, the user computing device may perform an analysis of dynamic time versus electrical property response associated with the seal.

At 1108, the user computing device may determine a remaining life of the seal and/or an estimated maintenance interval for the seal, for example, based on the estimated performance of the seal and/or the one or more electrical measurements. For example, the user computing device may compare the estimated performance of the seal and/or the one or more electrical measurements with pre-determined seal life trends associated with the specific material of the seal. The user computing device may send one or more notifications based on the determined remaining life of the seal and/or the estimated maintenance interval of the seal. For example, the user computing device may send one or more alerts based on the determined remaining life being less than a first predetermined threshold, based on the estimated maintenance interval being less than a second predetermined threshold, and/or the like. The estimated performance, the remaining life, and/or the maintenance interval of the seal, determined at 1106 or 1108, may be stored in memory (e.g., such as the memory 1206 shown in FIG. 12 and/or the memory 1406 shown in FIG. 14). The method 1100 may be repeated, periodically according to a pre-determined schedule, and/or on-demand in response to being triggered. The method 1100, may end, at 1112.

FIG. 12 illustrates a block diagram of an example computing device 1200 for use with a sealing arrangement (e.g., such as the sealing arrangement 200 shown in FIGS. 2A-2B, the sealing arrangement 300 shown in FIGS. 3A-3B, the sealing arrangement 400 shown in FIGS. 4A-4C, the sealing arrangement 500 shown in FIGS. 5A-5D, the sealing arrangement 800 shown in FIGS. 8A-8B, and/or the sealing arrangement 900 shown in FIGS. 9A-9B). The computing device 1200 may include a personal computer, such as a laptop or desktop computer, a tablet device, a cellular phone or smartphone, a server, or another type of computing device. The computing device 1200 may include a processor 1202, a communication interface 1204, a memory 1206, a display 1208, input devices 1210, output devices 1212, and/or a GPS circuit 1214. The computing device 1200 may include additional, different, or fewer components.

The processor 1202 may include one or more general purpose processors, special purpose processors, conventional processors, digital signal processors (DSPs), microprocessors, integrated circuits, a programmable logic device (PLD), application specific integrated circuits (ASICs), or the like. The processor 1202 may perform signal coding, data processing, image processing, power control, input/output processing, and/or any other functionality that enables the computing device 1200 to perform as described herein.

The processor 1202 may store information in and/or retrieve information from the memory 1206. The memory 1206 may include a non-removable memory and/or a removable memory. The non-removable memory may include random-access memory (RAM), read-only memory (ROM), a hard disk, or any other type of non-removable memory storage. The removable memory may include a subscriber identity module (SIM) card, a memory stick, a memory card, or any other type of removable memory. The memory may be local memory or remote memory external to the computing device 1200. The memory 1206 may store instructions which are executable by the processor 1202. Different information may be stored in different locations in the memory 1206.

The memory 1206 may comprise a computer-readable storage media or machine-readable storage media that stores computer-executable instructions for performing as described herein. The computer-executable instructions may comprise one or more portions of the procedures 1000 and/or 1100 for performing as described herein. The processor 1202 may access the instructions from memory 1206 for being executed to cause the processor 1202 to operate as described herein, or to operate one or more devices as described herein.

The processor 1202 that may communicate with other devices via the communication device 1204. The communication device 1204 may transmit and/or receive information over the network 1216, which may include one or more other computing devices. The communication device 1204 may perform wireless and/or wired communications. The communication device 1204 may include a receiver, transmitter, transceiver, or other device capable of performing wireless communications via an antenna. The communication device 1204 may be capable of communicating via one or more protocols, such as a cellular communication protocol, a Wi-Fi communication protocol, Bluetooth®, a near field communication (NFC) protocol, an internet protocol, another proprietary protocol, or any other radio frequency (RF) or communications protocol. The computing device 1200 may include one or more communication devices 1204.

The processor 1202 may be in communication with a display 1208 for providing information to a user. The information may be provided via a user interface on the display 1208. The information may be provided as an image generated on the display 1208. The display 1208 and the processor 1202 may be in two-way communication, as the display 1208 may include a touch-screen device capable of receiving information from a user and providing such information to the processor 1202.

The processor 1202 may be in communication with a GPS circuit 1214 for receiving geospatial information. The processor 102 may be capable of determining the GPS coordinates of the wireless communication device 1200 based on the geospatial information received from the GPS circuit 1214. The geospatial information may be communicated to one or more other communication devices to identify the location of the computing device 1200.

The processor 1202 may be in communication with input devices 1210 and/or output devices 1212. The input devices 1210 may include a camera, a microphone, a keyboard or other buttons or keys, and/or other types of input devices for sending information to the processor 1202. The display 1208 may be a type of input device, as the display 1208 may include touch-screen sensor capable of sending information to the processor 1202. The output devices 1212 may include speakers, indicator lights, or other output devices capable of receiving signals from the processor 1202 and providing output from the computing device 1200. The display 1208 may be a type of output device, as the display 1208 may provide images or other visual display of information received from the processor 1202.

FIG. 13 illustrates a block diagram of an example computing network system 1300 for use with a sealing arrangement (e.g., such as the sealing arrangement 200 shown in FIGS. 2A-2B, the sealing arrangement 300 shown in FIGS. 3A-3B, the sealing arrangement 400 shown in FIGS. 4A-4C, the sealing arrangement 500 shown in FIGS. 5A-5D, the sealing arrangement 800 shown in FIGS. 8A-8B, and/or the sealing arrangement 900 shown in FIGS. 9A-9B). The computing network system 1300 may include one or more computing devices 1330a-1330n that may be capable of communicating digital messages with one another, either directly or via the network 1320. The computing devices 1330-1330n may be user devices capable of initiating one or more measurements and/or performing processing of one or more measurements, for example using an interactive computing environment and providing real-time interactive data via the network 1320. The network 1320 may include a wired and/or wireless network. For example, the network 1320 may include a Wi-Fi communication network, a Wi-MAX communication network, a cellular communication network (e.g., CDMA, HSPA+, LTE, etc.), and/or a television white space (TVWS) communication network. The network 1320 may include one or more communication networks.

The one or more computing devices 1330a-1330n may be capable of communicating digital messages to and/or receiving digital messages from the computing device 1310 via the network 1320. The computing device 1310 may be a server, such as a web server, for providing a user interface to the computing devices 1330a-1330n. The computing device 1310 may be in communication with an application executing locally on the computing devices 1330a-1330n for providing a user interface at the computing devices. The display of information may be generated locally at the computing devices 1330a-1330n or at the computing device 1310 and provided via an application (e.g., a web browser) at the computing devices 1330a-1330n.

One or more of the computing devices 1330a-1330n may be operated by an administrative user capable of configuring sessions of an interactive computing environment that may be stored at the computing device 1310. The computing device operated by the administrative user may submit credentials to the computing device 1310 to allow the session to be configured. The session may be accessed by the computing devices 1330a-1330n via the network 1320.

FIG. 14 illustrates a block diagram of an example probe assembly 1400 for use with a sealing arrangement (e.g., such as the sealing arrangement 200 shown in FIGS. 2A-2B, the sealing arrangement 300 shown in FIGS. 3A-3B, the sealing arrangement 400 shown in FIGS. 4A-4C, the sealing arrangement 500 shown in FIGS. 5A-5D, the sealing arrangement 800 shown in FIGS. 8A-8B, and/or the sealing arrangement 900 shown in FIGS. 9A-9B). The probe assembly 1400 may include a processor 1402, a communication interface 1404, a memory 1406, and/or one or more sensors 1408. The probe assembly 1400 may include additional, different, or fewer components.

The processor 1402 may include one or more general purpose processors, special purpose processors, conventional processors, digital signal processors (DSPs), microprocessors, integrated circuits, a programmable logic device (PLD), application specific integrated circuits (ASICs), or the like. The processor 1402 may perform signal coding, data processing, image processing, power control, input/output processing, and/or any other functionality that enables the probe assembly 1400 to perform as described herein.

The processor 1402 may store information in and/or retrieve information from the memory 1406. The memory 1406 may include a non-removable memory and/or a removable memory. The non-removable memory may include random-access memory (RAM), read-only memory (ROM), a hard disk, or any other type of non-removable memory storage. The removable memory may include a subscriber identity module (SIM) card, a memory stick, a memory card, or any other type of removable memory. The memory may be local memory or remote memory external to the probe assembly 1400. The memory 1406 may store instructions which are executable by the processor 1402. The memory 1406 may store one or more measurements (e.g., such as real-time measurements measured by the one or more sensors 1408). Different information may be stored in different locations in the memory 1406.

The memory 1406 may comprise a computer-readable storage media or machine-readable storage media that stores computer-executable instructions for performing as described herein. The computer-executable instructions may comprise one or more portions of the procedures 1000 and/or 1100 for performing as described herein. The processor 1402 may access the instructions from memory 1406 for being executed to cause the processor 1402 to operate as described herein, or to operate one or more devices as described herein.

The processor 1402 that may communicate with other devices via the communication device 1404. The communication device 1404 may transmit and/or receive information over the network 1416, which may include one or more other computing devices and/or one or more other probe assemblies. The communication device 1404 may perform wireless and/or wired communications. The communication device 1404 may include a receiver, transmitter, transceiver, or other device capable of performing wireless communications via an antenna. The communication device 1404 may be capable of communicating via one or more protocols, such as a cellular communication protocol, a Wi-Fi communication protocol, Bluetooth®, a near field communication (NFC) protocol, an internet protocol, another proprietary protocol, or any other radio frequency (RF) or communications protocol. The probe assembly 1400 may include one or more communication devices 1404.

The processor 1402 may be in communication with the one or more sensors 1408. The one or more sensors 1408 may be configured to provide the real-time measurements of the one or more properties of an installed seal (e.g., such as the seal 108 shown in FIG. 1A, the seal 154 shown in FIG. 1B, the seal 260 shown in FIG. 2B, the seal 330 shown in FIGS. 3A-3B, the seal 460 shown in FIGS. 4B-4C, the seal 560 shown in FIGS. 5B and 5D, the seal 660 shown in FIG. 6, the seal 760 shown in FIG. 7, the seal 860 shown in FIG. 8B, and/or the seal 960 shown in FIG. 9B). The one or more sensors may include a pressure sensor, a temperature sensor, a humidity sensor, a proximity sensor, an optical sensor, a vibration sensor, resistance sensor, inductance sensor, and/or a capacitive sensor. For example, the one or more sensors may provide real time pressure measurements, temperature measurements, humidity measurements, proximity measurements, optical measurements, vibration measurements, resistance measurements, inductance measurements, and/or capacitance measurements.

The processor 1402 may be configured to enable real-time measurements of one or more properties of the installed seal. The real-time measurements of the one or more properties may enable determination of a performance metric of the installed seal based on the real-time measurements. The performance metric may enable determination of a remaining life of the installed seal and/or an estimated maintenance interval for the installed seal. In examples, the processor 1402 may determine the performance metric, the remaining life of the installed seal, and/or the estimated maintenance interval for the installed seal. The communication device 1414 may be configured to send the determined remaining life of the installed seal and/or the estimated maintenance interval for the installed seal to another computing device. Additionally or alternatively, the communication device 1414 may be configured to send the real-time measurements to another computing device.

1. A sealing arrangement comprising:
a housing assembly comprising a first housing portion and a second housing portion, the housing assembly defining a groove between the first housing portion and the second housing portion, the groove being defined by internal surfaces of one or more of the first housing portion or the second housing portion;
a seal having variable electrical properties, the seal configured to be received within the groove and abut the first housing portion and the second housing portion;
at least one probe assembly configured to extend into the groove defined by the housing assembly, the at least one probe assembly configured to enable real-time measurements of one or more properties of the seal; and
an insulator configured to electrically insulate at least a portion of the at least one probe assembly from the housing assembly.

2. The sealing arrangement of claim 1, wherein when extending into the groove, a probe tip of the at least one probe assembly is proximate to an outer surface of the seal.

3. The sealing arrangement of claim 1, wherein when extending into the groove, a probe tip of the at least one probe assembly is spaced away from an outer surface of the seal.

4. The sealing arrangement of claim 1, wherein when extending into the groove, a probe tip of the at least one probe assembly abuts an outer surface of the seal.

5. The sealing arrangement of claim 1, wherein the seal is an electrically conductive o-ring.

6. The sealing arrangement of claim 5, wherein the electrically conductive o-ring is homogenously conductive.

7. The sealing arrangement of claim 5, wherein the electrically conductive o-ring comprises a homogenous material that is electrically conductive.

8. The sealing arrangement of claim 5, wherein the at least one probe assembly comprises an electrical contact configured to abut the electrically conductive o-ring.

9. The sealing arrangement of claim 8, wherein the electrical contact comprises a spring-loaded contact configured to compensate for mechanical interference between the electrically conductive o-ring and the at least one probe assembly.

10. The sealing arrangement of claim 8, wherein the electrical contact is a first electrical contact, and wherein the at least one probe assembly comprises a second electrical contact configured to abut the housing assembly.

11. The sealing arrangement of claim 10, wherein the first electrical contact is electrically connected to an input lead and wherein the second electrical contact is electrically connected to an output lead.

12. The sealing arrangement of claim 11, wherein the input lead is configured to apply an electric current to the electrically conductive o-ring that travels through the electrically conductive o-ring and out of the output lead to measure the one or more properties of the electrically conductive o-ring while the electrically conductive o-ring remains within the groove.

13. The sealing arrangement of claim 1, wherein the housing assembly further comprises a clamp assembly configured to clamp the first housing portion to the second housing portion.

14. The sealing arrangement of claim 13, wherein the at least one probe assembly extends through the clamp assembly.

15. The sealing arrangement of claim 13, wherein the first housing portion is a first pipe section having a first flange and the second housing portion is a second pipe section having a second flange.

16. The sealing arrangement of claim 1, wherein the real-time measurements of the one or more properties enable determination of a performance metric of the seal based on the real-time measurements, and wherein the performance metric enables determination of a remaining life of the seal or an estimated maintenance interval for the seal.

17. The sealing arrangement of claim 1, wherein the at least one probe assembly comprises a sensor configured to provide the real-time measurements of the one or more properties of the seal, and wherein the sensor comprises one or more of a pressure sensor, a temperature sensor, a humidity sensor, a proximity sensor, an optical sensor, a vibration sensor, or a capacitive sensor.

18. The sealing arrangement of claim 1, wherein the electrical properties of the seal comprise one or more of resistance, capacitance, or inductance.

19. The sealing arrangement of claim 1, wherein the electrical properties of the seal vary when the seal is compressed by a force, when a current is applied to the seal, when the seal is exposed to application conditions, when the seal is chemically attacked, when the seal is physically attacked, or when the seal is exposed to a varying temperature.

20. The sealing arrangement of claim 1, wherein the at least one probe assembly is configured to send and receive wireless messages.
